(19) United States
(12) Patent Application Publication
(10) Pub. No.: US 2026/0054476 A1
(43) Pub. Date: Feb. 26, 2026

(54) FLEXIBLE MICROCAVITIES, MULTI-FUNCTION FLEXIBLE HYBRID ELECTRONICS INTEGRATING THE SAME, AND SCREEN-PRINTING PROCESSES FOR FABRICATING THE SAME

(71) Applicant: University of Florida Research Foundation, Inc., Gainesville, FL (US)

(72) Inventors: Toshikazu Nishida, Gainesville, FL (US); Cameron Anderson, Gainesville, FL (US); Hugh Fan, Gainesville, FL (US)

(21) Appl. No.: 19/299,686

(22) Filed: Aug. 14, 2025

Related U.S. Application Data
(60) Provisional application No. 63/685,908, filed on Aug. 22, 2024.

(51) Int. Cl. B41F 15/12; B41F 15/34; B41F 15/40

(52) U.S. Cl. CPC B41F 15/12; B41F 15/34; B41F 15/405

(57) ABSTRACT

Described are systems, methods, devices, apparatuses, and materials suitable for fabricating flexible microcavity structures and integrating flexible microcavity structures into multi-functional flexible hybrid electronics and electronic components, as well as systems, devices, apparatuses, methods, and computer program products for screen-printing flexible microcavity structures and for integrating flexible microcavity structures into multi-functional flexible hybrid electronics.

### CROSS-REFERENCE TO RELATED APPLICATIONS

This application claims the benefit of priority to U.S. Provisional Patent Application Ser. No. 63/685,908, which was filed Aug. 22, 2024 and entitled “A Fully Screen-Printed Process for the Fabrication and Integration of Flexible Microcavity Structures into Multi-Functional Flexible Hybrid Electronics,” the entire disclosure of which is hereby incorporated herein by reference in its entirety for all purposes.

### STATEMENT REGARDING GOVERNMENT SUPPORT

This invention was made with government support under 1939009 awarded by the National Science Foundation. The government has certain rights in the invention.

### FIELD

The presently disclosed subject matter relates generally to methods and apparatuses for preparing flexible microcavity structures in multi-functional flexible hybrid electronics, and more specifically to screen-printing methods and apparatuses for carrying out the same.

### BACKGROUND

Microcavities, such as optical microcavities, can be used to confine light in small volumes using resonance. Microcavities can include micro-scale conduits, lumens, cavities, chambers, pores, and/or the like. For example, microcavity arrays can be used for cell isolation and analysis, micro-needles can be used for unique drug delivery systems, and microfluidic channels may enable lab-on-a-chip applications such as for cell culture growth, disease diagnosis, and tissue-on-chip devices. As a further example, microcavities can be used in micro-electromechanical systems (MEMS) transducers, which can be used in pressure transducers, gyroscopes, accelerometers, and the like. Further information about microsystems and the like can be found in Bejarano, et al. (2009) “Screen printing as a holistic manufacturing method for multifunctional microsystems and microreactors,” J. Micromech. Microeng, 19, 115007, the entire disclosure of which is hereby incorporated herein by reference in its entirety for all purposes.

In the field of flexible sensing, such as for wearable biosensors and the like, flexible hybrid electronics (FHEs) can be used. FHEs can include flexible, stretchable, compressible, elongatable, and/or conformable devices and electronic components. The dynamic form factor of FHEs may provide for electronics devices/components with improved durability, conformability, sensor contact, and/or the like. However, FHEs do not typically include microcavities. Conventionally, optical microcavities in conformationally static MEMS transducers, microcavity arrays, micro-scale conduits, micro-needles, microbioreactors, or the like, are often not suitable for use in wearable technologies and in other applications where FHEs may be beneficial. Furthermore, microcavities, especially for use in electronics and electronic components, are conventionally formed using subtractive manufacturing techniques, which poses a challenge for the development of flexible sensors due to, e.g., material incompatibility, damage due to chemical or radiation exposure, and temperature constraints, among other issues. As such, there is a need for microcavities that can be used in FHEs and non-subtractive methods for forming the same.

### BRIEF SUMMARY

Described herein are systems, devices, apparatuses, and materials suitable for fabricating flexible microcavity structures and integrating flexible microcavity structures into multi-functional flexible hybrid electronics and electronic components, as well as systems, devices, apparatuses, methods, and computer program products for screen-printing flexible microcavity structures and for integrating flexible microcavity structures into multi-functional flexible hybrid electronics.

According to an embodiment, a method can be carried out that comprises: providing a substrate comprising a planar substrate material and a first electrode material coupled to at least a portion of a top surface of the planar substrate material; disposing one or more volumes of an ink through one or more patterned screens onto a top surface of the substrate; at least partially curing the one or more volumes of the ink to form a plurality of microstructures on the top surface of the substrate, wherein the top surface of the substrate and the plurality of microstructures define one or more microcavities; and disposing a capping film over at least a portion of the plurality of microstructures to encapsulate at least a portion of the one or more microcavities between the top surface of the substrate and a bottom surface of the capping film.

In some embodiments, the at least partially curing the one or more volumes of the ink is performed using a curing device selected from among: a heat source, a light source, a light emitting diode, a lamp, a bulb, an ultraviolet emission source, a heater, or a mercury vapor lamp. In some embodiments, the curing device is disposed within or on a retractable sheet mounted on standoff rollers configured to move along board rails positioned between or about the substrate and the one or more patterned screens. In some embodiments, said disposing the capping film over at least a portion of the plurality of microstructures forms one or more inlets into the one or more microcavities and one or more outlets from the one or more microcavities. In some embodiments, the substrate comprises a planar substrate material and a first electrode material coupled to at least a portion of the top surface of the planar substrate material. In some embodiments, the method further comprises: disposing a second electrode material onto at least a portion of a top surface of the capping film. In some embodiments, the one or more volumes of the ink, once screen-printed and supported on the top surface of the substrate, forms one or more dielectric layers supported on the top surface of the substrate. In some embodiments, the ink comprises one or more of: a resin, an isobornyl acrylate-based resin, PDMS, a ceramic, an acrylic, polystyrene, polycarbonate, polyvinyl chloride, a conductive ink, a solvent, a binder, an additive, a pigment, a carrier, or a rheologically modifier.

In some embodiments, the method further comprises: disposing a first electrode material onto the substrate to form the top surface of the substrate. In some embodiments, the method further comprises: disposing a laminate film over top surfaces of the plurality of microstructures to encapsulate the plurality of microcavities between a bottom surface of the laminate film and the top surface of the substrate. In some embodiments, the method further comprises: disposing a second electrode material onto a top surface of the laminate film. In some embodiments, the method further comprises: disposing, onto the top surface of the laminate film or a top surface of the one more volumes of ink disposed on the substrate, one or more of: an electrode layer, a resin layer, or a laminate layer to create additional microcavities in a vertically stacked configuration, with or without interconnection between the plurality of microcavities and the additional microcavities. In some embodiments, the method further comprises: disposing a graphic layer onto the top surface of the substrate before screen-printing the one or more volumes of the ink onto the top surface of the substrate in order to dispose one or more fiducials on the top surface of the substrate. In some embodiments, the method further comprises: removing at least a portion of an insulating layer of the substrate to expose at the top surface of the substrate one or more electrical traces or one or more fiducials. In some embodiments, the method further comprises: positioning one or more patterned screens above or onto a top surface of a substrate, the substrate comprising a first electrode material coupled to at least a portion of the top surface of the planar substrate material.

According to an embodiment, a method can be carried out that comprises: disposing a first patterned screen above a substrate; screen-printing a first portion of a resin ink through the first patterned screen and onto at least a portion of a top surface of the substrate; after screen-printing the first portion of the resin ink through the first patterned screen, disposing a retractable ultraviolet light emitting diodes between the first patterned screen and the substrate; emitting ultraviolet light from the ultraviolet light emitting diodes to at least partially cure the first portion of the resin ink screen-printed onto the top surface of the substrate; retracting the retractable ultraviolet light emitting diodes; disposing a second patterned screen above the substrate; screen-printing a second portion of the resin ink through the second patterned screen and onto one or both of at least a portion of the top surface of the substrate or at least a portion of a top surface of the first portion of the resin ink previously screen-printed onto at least a portion of the top surface of the substrate; after screen-printing the second portion of the resin ink through the second patterned screen, disposing the retractable ultraviolet light emitting diodes between the second patterned screen and the substrate; and emitting ultraviolet light from the ultraviolet light emitting diodes to at least partially cure the second portion of the resin ink to form a plurality of microstructures, wherein the top surface of the substrate and the plurality of microstructures define a plurality of microcavities therebetween.

In some embodiments, the ultraviolet light emitting diodes are comprised within a mercury vapor lamp. In some embodiments, the first and second portions of the resin ink, once screen-printed and supported on the top surface of the substrate, form one or more dielectric layers supported on the top surface of the substrate. In some embodiments, the screen-printing of the second portion of the resin ink onto one or more of the top surface of the substrate or the top surface of the first portion of the resin ink screen-printed onto the top surface of the substrate forms one or more microcavities above the top surface of the substrate. In some embodiments, the method further comprises: disposing a first electrode material onto the substrate to form the top surface of the substrate; after screen-printing the second portion of the resin ink through the second patterned screen and at least partially curing the second portion of the resin ink, disposing a laminate film over top surfaces of the plurality of microstructures to encapsulate the plurality of microcavities between a bottom surface of the laminate film and the top surface of the substrate; and disposing a second electrode material onto a top surface of the laminate film.

According to an embodiment, a method can be carried out that comprises: disposing a cross-linkable printing ink onto a top surface of a printing screen, the printing screen comprising apertures therethrough according to a first portion of a printed structure; causing a bottom surface of the printing screen to contact a top surface of a substrate, thereby transferring at least a portion of the cross-linkable printing ink onto a portion of the top surface of the substrate; moving at least one of the printing screen or the substrate to form a nonzero distance therebetween; transferring the substrate to a thermal oven or UV curing chamber to cross-link a thermally curable or UV sensitive cross-linkable ink, respectively; or moving a retractable light emission source or heat source into the nonzero distance formed between the printing screen and the substrate; and causing the retractable light emission source or heat source to emit ultraviolet light or heat onto the top surface of the substrate to cause cross-linking of the portion of the cross-linkable printing ink transferred onto the top surface of the substrate in situ without having to remove the substrate to cure the printing ink in a separate curing chamber. The in situ curing of the printing ink is essential to enable the high accuracy registration for the accurate fabrication and integration of flexible microcavities in a fully screen-printed process. Additionally or alternatively, a solvent-based particle suspension ink can be used, such as a silver-containing conductive ink, a carbon-containing conductive ink, and/or the like. Additionally or alternatively, a retractable source can also emit heat to facilitate solvent-based ink curing of certain inks.

According to an embodiment, a method can be carried out that comprises: disposing a cross-linkable printing ink through one or more patterned screens onto a top surface of a substrate; emitting ultraviolet light from one or more ultraviolet light emitting diodes to cure the cross-linkable printing ink to form a plurality of microstructures on the top surface of the substrate, wherein the top surface of the substrate and the plurality of microstructures define one or more microcavities; and disposing a capping film over at least a portion of the plurality of microstructures to encapsulate at least a portion of the one or more microcavities between the top surface of the substrate and a bottom surface of the capping film.

According to an embodiment, a method can be carried out that comprises: providing a substrate comprising a planar substrate material and a first electrode material coupled to at least a portion of a top surface of the planar substrate material; disposing a cross-linkable printing ink through one or more patterned screens onto a top surface of the substrate; emitting ultraviolet light from one or more ultraviolet light emitting diodes to cure the cross-linkable printing ink to form a plurality of microstructures on the top surface of the substrate, wherein the top surface of the substrate and the plurality of microstructures define one or more microcavities; and disposing a capping film over at least a portion of the plurality of microstructures to encapsulate at least a portion of the one or more microcavities between the top surface of the substrate and a bottom surface of the capping film.

According to an embodiment, a method can be carried out that comprises: providing a substrate comprising a planar substrate material and a first electrode material coupled to at least a portion of a top surface of the planar substrate material; disposing a cross-linkable printing ink through one or more patterned screens onto a top surface of the substrate; emitting ultraviolet light from one or more ultraviolet light emitting diodes to cure the cross-linkable printing ink to form a plurality of microstructures on the top surface of the substrate, wherein the top surface of the substrate and the plurality of microstructures define one or more microcavities; disposing a capping film over at least a portion of the plurality of microstructures to encapsulate at least a portion of the one or more microcavities between the top surface of the substrate and a bottom surface of the capping film; and disposing a second electrode material onto at least a portion of a top surface of the capping film.

According to an embodiment, a method can be carried out that comprises: disposing a first patterned screen above a substrate; screen-printing a first portion of a cross-linkable printing ink through the first patterned screen and onto at least a portion of a top surface of the substrate; disposing a retractable sheet comprising flexible ultraviolet light emitting diodes between the first patterned screen and the substrate; emitting ultraviolet light from the ultraviolet light emitting diodes to cure the first portion of the cross-linkable printing ink screen-printed onto the top surface of the substrate; retracting the retractable sheet comprising the flexible ultraviolet light emitting diodes; disposing the first patterned screen above the substrate; screen-printing a second portion of the cross-linkable printing ink through the first patterned screen and onto a top surface of the first portion of the cross-linkable printing ink previously screen-printed onto at least a portion of the top surface of the substrate; disposing the retractable sheet comprising the flexible ultraviolet light emitting diodes between the second patterned screen and the substrate; and emitting ultraviolet light from the ultraviolet light emitting diodes to cure the second portion of the cross-linkable printing ink to form a plurality of microstructures, wherein the top surface of the substrate and the plurality of microstructures define a plurality of microcavities therebetween.

According to an embodiment, a method can be carried out that comprises: disposing a first patterned screen above a substrate; screen-printing a first portion of a cross-linkable printing ink through the first patterned screen and onto at least a portion of a top surface of the substrate; disposing a retractable sheet comprising flexible ultraviolet light emitting diodes between the first patterned screen and the substrate; emitting ultraviolet light from the ultraviolet light emitting diodes to cure the first portion of the cross-linkable printing ink screen-printed onto the top surface of the substrate; retracting the retractable sheet comprising the flexible ultraviolet light emitting diodes; disposing a second patterned screen above the substrate; screen-printing a second portion of the cross-linkable printing ink through the second patterned screen and onto one or both of at least a portion of the top surface of the substrate or at least a portion of a top surface of the first portion of the cross-linkable printing ink previously screen-printed onto at least a portion of the top surface of the substrate; disposing the retractable sheet comprising the flexible ultraviolet light emitting diodes between the second patterned screen and the substrate; and emitting ultraviolet light from the ultraviolet light emitting diodes to cure the second portion of the cross-linkable printing ink to form a plurality of microstructures, wherein the top surface of the substrate and the plurality of microstructures define a plurality of microcavities therebetween.

According to an embodiment, a method can be carried out that comprises: disposing a first patterned screen above a substrate; screen-printing a first portion of a first cross-linkable printing ink through the first patterned screen and onto at least a portion of a top surface of the substrate; disposing a retractable sheet comprising flexible ultraviolet light emitting diodes between the first patterned screen and the substrate; emitting ultraviolet light from the ultraviolet light emitting diodes to cure the first portion of the first cross-linkable printing ink screen-printed onto the top surface of the substrate; retracting the retractable sheet comprising the flexible ultraviolet light emitting diodes; disposing a second patterned screen above the substrate; screen-printing a first portion of a second cross-linkable printing ink through the second patterned screen and onto one or both of at least a portion of the top surface of the substrate or at least a portion of a top surface of the first portion of the first cross-linkable printing ink previously screen-printed onto at least a portion of the top surface of the substrate; disposing the retractable sheet comprising the flexible ultraviolet light emitting diodes between the second patterned screen and the substrate; and emitting ultraviolet light from the ultraviolet light emitting diodes to cure the first portion of the second cross-linkable printing ink to form a plurality of microstructures, wherein the top surface of the substrate and the plurality of microstructures define a plurality of microcavities therebetween.

According to an embodiment, a method can be carried out that comprises: providing a substrate comprising a planar substrate material and a first electrode material coupled to at least a portion of a top surface of the planar substrate material; disposing a resin ink through one or more patterned screens onto a top surface of the substrate; emitting ultraviolet light from one or more ultraviolet light emitting diodes to cure the resin ink to form a plurality of microstructures on the top surface of the substrate, wherein the top surface of the substrate and the plurality of microstructures define one or more microcavities; and disposing a capping film over at least a portion of the plurality of microstructures to encapsulate at least a portion of the one or more microcavities between the top surface of the substrate and a bottom surface of the capping film.

In some embodiments, said disposing the capping film over at least a portion of the plurality of microstructures forms one or more inlets into the one or more microcavities and one or more outlets from the one or more microcavities. In some embodiments, the substrate comprises a planar substrate material and a first electrode material coupled to at least a portion of the top surface of the planar substrate material.

In some embodiments, the method further comprises: disposing a second electrode material onto at least a portion of a top surface of the capping film. In some embodiments, the one or more light sources (e.g., ultraviolet light emitting diodes, mercury vapor lamp, etc.) are within or on a retractable sheet mounted on standoff rollers configured to move along board rails positioned between or about the substrate and the one or more patterned screens.

In some embodiments, the substrate is a semiconductor substrate that comprises one or more of: silicone, germanium, gallium, antimony, boron, carbon, arsenic, selenium, sulfur, or tellurium. In some embodiments, the first and second portions of the resin ink, once screen-printed and supported on the top surface of the substrate, form one or more dielectric layers supported on the top surface of the substrate. In some embodiments, the resin ink comprises an isobornyl acrylate-based resin. In some embodiments, the screen-printing of the second portion of the resin ink onto one or more of the top surface of the substrate or the top surface of the first portion of the resin ink screen-printed onto the top surface of the substrate forms one or more microcavities above the top surface of the substrate.

In some embodiments, the method can further comprise: disposing a first electrode material onto the substrate to form the top surface of the substrate. In some embodiments, the method can further comprise: disposing a laminate film over top surfaces of the plurality of microstructures to encapsulate the plurality of microcavities between a bottom surface of the laminate film and the top surface of the substrate. In some embodiments, the method can further comprise: disposing a second electrode material onto a top surface of the laminate film. In some embodiments, the method can further comprise: disposing a graphic layer onto the top surface of the substrate before screen-printing the first portion of the resin ink onto the top surface of the substrate in order to dispose one or more fiducials on the top surface of the substrate. In some embodiments, the method can further comprise: removing at least a portion of an insulating layer of the substrate to expose at the top surface of the substrate one or more electrical traces or one or more fiducials. In some embodiments, additional conductive layers and dielectric layers can be deposited on top of the laminating film to form internal connections and microcavities, or stacked structures. This could also include intermediary removals of portions of the laminating film, e.g., to create vias.

According to an embodiment, a method can be carried out that comprises: disposing a first patterned screen above a substrate; screen-printing a first portion of a resin ink through the first patterned screen and onto at least a portion of a top surface of the substrate; disposing a retractable sheet comprising flexible ultraviolet light emitting diodes between the first patterned screen and the substrate; emitting ultraviolet light from the ultraviolet light emitting diodes to cure the first portion of the resin ink screen-printed onto the top surface of the substrate; retracting the retractable sheet comprising the flexible ultraviolet light emitting diodes; disposing a second patterned screen above the substrate; screen-printing a second portion of the resin ink through the second patterned screen and onto one or both of at least a portion of the top surface of the substrate or at least a portion of a top surface of the first portion of the resin ink previously screen-printed onto at least a portion of the top surface of the substrate; disposing the retractable sheet comprising the flexible ultraviolet light emitting diodes between the second patterned screen and the substrate; and emitting ultraviolet light from the ultraviolet light emitting diodes to cure the second portion of the resin ink to form a plurality of microstructures, wherein the top surface of the substrate and the plurality of microstructures define a plurality of microcavities therebetween.

In some embodiments, the ultraviolet light emitting diodes are comprised within a mercury vapor lamp. In some embodiments, the substrate is a semiconductor substrate that comprises one or more of: silicone, germanium, gallium, antimony, boron, carbon, arsenic, selenium, sulfur, or tellurium. In some embodiments, the first and second portions of the resin ink, once screen-printed and supported on the top surface of the substrate, form one or more dielectric layers supported on the top surface of the substrate. In some embodiments, the resin ink comprises an isobornyl acrylate-based resin. In some embodiments, the screen-printing of the second portion of the resin ink onto one or more of the top surface of the substrate or the top surface of the first portion of the resin ink screen-printed onto the top surface of the substrate forms one or more microcavities above the top surface of the substrate.

In some embodiments, the method further comprises: disposing a first electrode material onto the substrate to form the top surface of the substrate. In some embodiments, the method further comprises: disposing a laminate film over top surfaces of the plurality of microstructures to encapsulate the plurality of microcavities between a bottom surface of the laminate film and the top surface of the substrate. In some embodiments, the method can further comprise: disposing a second electrode material onto a top surface of the laminate film. In some embodiments, the method further comprises: disposing a graphic layer onto the top surface of the substrate before screen-printing the first portion of the resin ink onto the top surface of the substrate in order to dispose one or more fiducials on the top surface of the substrate. In some embodiments, the method further comprises: removing at least a portion of an insulating layer of the substrate to expose at the top surface of the substrate one or more electrical traces or one or more fiducials.

According to embodiments, an apparatus can be provided that comprises means for performing at least a portion of any of the methods described herein.

According to embodiments, an apparatus can be provided that comprises at least one processor and at least one memory storing instructions thereon that, when executed by the at least one processor, cause the apparatus to perform at least a portion of any of the methods described herein.

According to another embodiment, a computer program product can be provided that comprises a non-transitory computer-readable storage medium comprising instructions, such as in the form of computer-executable program codes, that when executed by one or more processors, causes an apparatus to perform at least at least a portion of any of the methods described herein.

### BRIEF DESCRIPTION OF THE DRAWINGS

The present disclosure more fully describes various embodiments with reference to the accompanying drawings. It should be understood that some, but not all, embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

FIG. 1 is a block flow diagram of an apparatus for screen-printing of flexible microcavities, according to certain embodiments described herein.

FIG. 2 is a block flow diagram of an apparatus for screen-printing of flexible microcavities, according to certain embodiments described herein.

FIG. 3 is a block flow diagram of an apparatus for screen-printing of flexible microcavities, according to certain embodiments described herein.

FIG. 4 is a block flow diagram of an apparatus for screen-printing of flexible microcavities, according to certain embodiments described herein.

FIG. 5 illustrates an example of a printing screen ribbon for screen-printing of flexible microcavities, according to certain embodiments described herein.

FIG. 6 illustrates an example of a printing screen ribbon for screen-printing of flexible microcavities, according to certain embodiments described herein.

FIG. 7 illustrates an example apparatus for 3D screen-printing of flexible microcavities for use in flexible hybrid electronics (FHEs), according to certain embodiments described herein.

FIG. 8 illustrates an example apparatus for laminating or capping 3D screen-printed flexible microcavities for use in FHEs, according to certain embodiments described herein.

FIG. 9A is an example of a roller standoff assembly for a 3D screen-printing device for printing flexible microcavities for use in FHEs, according to certain embodiments described herein.

FIG. 9B is a subset of the roller standoff assembly illustrated in FIG. 9A.

FIG. 9C is a subset of the roller standoff assembly illustrated in FIG. 9A.

FIG. 9D is a subset of the roller standoff assembly illustrated in FIG. 9A.

FIG. 10 is an illustration of a system for biosensing, according to certain embodiments described herein.

FIG. 11 illustrates a process flow diagram for a process of 3D screen-printing flexible microcavities for use in FHEs, according to certain embodiments described herein.

FIG. 12 is a photograph of a portion of a system for 3D screen-printing of flexible microcavities, according to certain embodiments described herein.

FIG. 13 is a mid-plane cross-section image of a fabricated microscale channel showing variation in channel width between different orientations of the fabricated microscale channel, according to an embodiment.

FIG. 14 is a cross-section of a fabricated device images using x-ray computer tomography, according to an embodiment described herein.

FIG. 15 is a graph of average channel width of a fabricated microscale channel as a function of channel height relative to the number of screen-printed layers, according to certain embodiments described herein.

FIG. 16 is a side-view cross-section of a fabricated microcavity channel, according to certain embodiments described here.

FIG. 17 is a photograph of a system for testing performance of 3D screen printed microcavity channels, and the inset provides a more detailed view of a nanoport fitting thereof, according to certain embodiments described herein.

FIG. 18 is a graph of measured capacitance of microfluidic channel samples for 3D screen printed microcavity channels, according to several embodiments described herein.

FIG. 19 is a photograph of a printed microfluidic channel test structure comprising a microfluidic channel fabricated using a 3D screen printed fabrication process, according to certain embodiments described herein.

FIG. 20 is a photograph of an example screen-printed sensing prototype incorporating fabricated microcavities as sensors directly onto the substrate, reducing the need for additional complex fabrication steps, according to certain embodiments described herein.

FIG. 21 is an illustration of profile height and width calculations from measured cavity profiles for microscale channels fabricated using a 3D screen printing fabrication process, according to certain embodiments described herein.

FIG. 22 is a graph of overlayed sample height and lateral distance for samples having different numbers of deposited layers for a designated cavity width of 1 mm, according to certain embodiments described herein.

FIG. 23 is a graph illustrating the reduction of cavity width as a function of the number of layers for a particular ink while keeping curing conditions identical therebetween, according to certain embodiments described herein.

FIG. 24 illustrates an equivalent circuit model of a sample capacitive sensor fabricated using a 3D screen printed fabrication process, according to certain embodiments described herein.

FIG. 25 is a graph of measured capacitance of microfluidic channel samples for 3D screen printed microcavity channels, according to several embodiments described herein.

FIG. 26 is a schematic of a design for a sweat sensor comprising microscale channels oriented in a ring shape to improve flow rate of sweat samples therethrough, according to several embodiments described herein.

FIG. 27 is a design for a 3D screen printed capacitive sweat sensor fabricated using multiple screens and alternative channels for sweat sample collection and communication therethrough, according to several embodiments described herein.

FIG. 28 is a photograph of a prototype sensor for a capacitive sweat sensor or a capacitive sweat sensing device or system, according to several embodiments described herein.

FIG. 29 is a photograph of a prototype sensor for a capacitive sweat sensor or a capacitive sweat sensing device or system, according to several embodiments described herein.

FIG. 30 illustrates a system for 3D screen-printing flexible microcavities for use in FHEs, according to certain embodiments described herein.

FIG. 31 is a graph that illustrates percent change in capacitance of a sensor as a function of liquid volume for a select set of sensor samples comprising micro-scale channels fabricated according to certain embodiments described herein.

FIG. 32 is a graph that illustrates sensor response (normalized capacitance change) versus time for a 3D screen printed microfluidic channel, fabricated according to an embodiment described herein, at dispense rates of 0.5 uL/min., 1 uL/min., and 2 uL/min.

FIG. 33 illustrates an example computing device configured for controlling systems and apparatuses for 3D screen-printing flexible microcavities for use in FHEs, according to certain embodiments described herein.

FIG. 34 illustrates an example external computing device configured for controlling systems and apparatuses for 3D screen-printing flexible microcavities for use in FHEs, according to certain embodiments described herein.

FIG. 35 is a block flow diagram of a method for screen-printing of flexible microcavities, according to certain embodiments described herein.

FIG. 36 is a block flow diagram of a method for screen-printing of flexible microcavities, according to certain embodiments described herein.

FIG. 37 is a block flow diagram of a method for screen-printing of flexible microcavities, according to certain embodiments described herein.

FIG. 38 is a block flow diagram of a method for screen-printing of flexible microcavities, according to certain embodiments described herein.

FIG. 39 is a block flow diagram of a method for screen-printing of flexible microcavities, according to certain embodiments described herein.

FIG. 40 is a block flow diagram of a method for screen-printing of flexible microcavities, according to certain embodiments described herein.

### DETAILED DESCRIPTION

Microcavities can include micro-scale conduits, lumens, cavities, chambers, pores, and/or the like. For example, microcavity arrays can be used for cell isolation and analysis, micro-needles can be used for unique drug delivery systems, and microfluidic channels may enable lab-on-a-chip applications such as for cell culture growth, disease diagnosis, and tissue-on-chip devices. As a further example, microcavities can be used in micro-electromechanical systems (MEMS) transducers, which can be used in pressure transducers, gyroscopes, accelerometers, and the like. Some microcavities, such as optical microcavities, can be used to confine light in small volumes using resonance.

Microcavities have also become a prominent component of research in many fields, with applications from engineering to biology. Optical microcavities, which confine light in small volumes using resonance, are a prominent field of research with applications from quantum optics to bio and chemical sensing. In the field of biomedical research, microcavity arrays have been widely used for cell isolation and analysis, and micro-needles have been developed for drug delivery systems. Microfluidic channels enable lab-on-a-chip applications such as cell culture, disease diagnosis, and tissue-on-chip devices. Additionally, MEMS transducers rely heavily on fabricated microcavities, and have been shown to be particularly effective for a wide range of sensing applications, such as pressure transducers, gyroscopes, and accelerometers. MEMS devices are typically fabricated through surface or bulk micromachining, which utilizes photolithographic patterning and etching processes on common semiconductor substrates such as Si or Ge.

Flexible sensing has emerged as a prominent field in recent years as the demand for wearable biosensors has grown. Flexible hybrid electronics (FHE) are flexible, stretchable, compressible, elongatable, or conformable devices and electronic components. Typically, FHEs incorporate off-the-shelf rigid electronic components, however the rigidity of the off-the-shelf electronic components limits the flexibility of the FHEs. Oftentimes, FHE are implemented within or between a polymer film or the like. The dynamic form factor of FHE can provide for improved durability, conformability, sensor contact, or the like. However, the use of microcavities, such as optical microcavities, in conventional, conformationally static, MEMS transducers or the like, is often not suitable for use in wearable technologies and in other applications. Furthermore, traditional subtractive manufacturing techniques pose a challenge for the development of flexible sensors, due to material compatibility and temperature constraints.

In the field of flexible sensing, such as for wearable biosensors and the like, FHEs can be used. The dynamic form factor of FHEs may provide for electronics devices/components with improved durability, conformability, sensor contact, and/or the like. However, FHEs do not typically include microcavities. Conventionally, microcavities such as optical microcavities are rigid and are fabricated using subtractive manufacturing processes, making them more suitable for use in conformationally static devices. Use of flexible microcavities in devices/components such as MEMS transducers, microcavity arrays, micro-scale conduits, micro-needles, microbioreactors, or the like is desirable, but not typically possible with the rigid off-the-shelf microcavity structures or conventional subtractive approaches for making the same in situ. Furthermore, microcavities, especially for use in electronics and electronic components, are conventionally formed using subtractive manufacturing techniques, which poses a challenge for the development of flexible sensors due to, e.g., material incompatibility, damage due to chemical or radiation exposure, and temperature constraints, among other issues.

FHEs often combine printed components with advanced CMOS-based elements on a flexible polymer film substrate. Applications of printed chips range from monitoring temperature and vibration in industrial settings to flexible sensors for skin applications. These chips are particularly useful in scenarios where rigid alternatives are impractical or challenging to replace. Various printing technologies can be used in the field of printed electronics. Inkjet printing, commonly used for low-volume applications, offers a cost-effective but relatively slow option for fabricating FHEs. Additionally, offset and gravure printing have gained popularity due to their ability to precisely layer materials at high volumes. Gravure printing was initially used for high-quality art prints, while offset printing has been a staple in newspaper production.

The success of printed electronics often hinges on ink chemistry, stability, and precise calibration during the bonding process. As with the fabrication of all semiconductors, repeatability, consistency, and economies of scale are essential considerations.

While FHE devices do not necessarily require all components to be flexible, all FHEs require that at least some component(s) of the FHE are flexible, requiring at the microscale that at least one component of an FHE must be fabricated from a material or materials that are flexible in nature. Some electronic chips are thin and small enough to be manufactured using metal oxide lithography directly on the flexible substrate, bypassing the need for printing. However, in many applications, printing of flexible chips and the like for FHEs is required.

Transferring silicon circuits to a flexible substrate without damage also poses challenges. Among transfer techniques that exist, all are subtractive in nature. Brute force methods involve mechanical and/or chemical polishing to thin the semiconductor, while epitaxial layer liftoff methods selectively remove an embedded sacrificial layer, often through etching, and mechanical exfoliation via substrate cracking (spalling) deposits a high-fracture-toughness, pre-tensioned nickel film onto the substrate; tape is then used to pull the nickel layer away until the underlying substrate fractures below the buried oxide (e.g., approximately 20 microns below the buried oxide).

Additive manufacturing can often be used for printing complex surface textures, microstructures, etc. However, additive manufacturing at microscale is typically carried out by hot thermoplastic filament deposition in a layer-by-layer approach. Such hot-melt printing, extrusion printing, 3D printing, and inkjet printing approaches are typically not suitable for FHE formation or for the formation of microcavities for use in FHEs. There are several reasons for this, including that flexible cavity structures can be fabricated in laboratory environments, but challenges arise when these structures are integrated into a larger flexible sensing device or FHE system. Further, while additive manufacturing (3D printing) can be used to fabricate, conductive traces, and electrodes, other subtractive fabrication techniques such as laser etching or soft lithography are typically used for forming flexible microcavities in the 3D printed structure for form the finished FHE device. However, combining additive manufacturing techniques with the subsequent use of subtractive manufacturing techniques increases the complexity, duration, and cost of manufacturing FHEs with microcavities formed therein.

As such, there is a need for microcavities that can be used in FHEs and non-subtractive methods for forming the FHE and microcavities simultaneously and/or within the same additive manufacturing process/step.

Various embodiments of the present disclosure will now be described more fully hereinafter with reference to the accompanying drawings, in which some, but not all embodiments of the disclosed systems, methods, and apparatuses are shown. Indeed, the disclosed systems, methods, and apparatuses may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “exemplary” are used to be examples with no indication of quality level. Like numbers refer to like elements throughout.

As used herein, the terms “instructions,” “file,” “designs,” “data,” “content,” “information,” and similar terms may be used interchangeably, according to some example embodiments of the present disclosure, to refer to data capable of being transmitted, received, operated on, displayed, and/or stored. Thus, use of any such terms should not be taken to limit the spirit and scope of the disclosure. Further, where a computing device is described herein to receive data from another computing device, it will be appreciated that the data may be received directly from the other computing device or may be received indirectly via one or more computing devices, such as, for example, one or more servers, relays, routers, network access points, base stations, and/or the like.

As used herein, the term “computer-readable medium” refers to any medium configured to participate in providing information to a processor, including instructions for execution. Such a medium may take many forms, including, but not limited to a non-transitory computer-readable storage medium (for example, non-volatile media, volatile media), and transmission media. Transmission media include, for example, coaxial cables, copper wire, fiber optic cables, and carrier waves that travel through space without wires or cables, such as acoustic waves and electromagnetic waves, including radio, optical, and infrared waves. Signals include man-made transient variations in amplitude, frequency, phase, polarization, or other physical properties transmitted through the transmission media. Examples of non-transitory computer-readable media include a floppy disk, a flexible disk, hard disk, magnetic tape, any other non-transitory magnetic medium, a compact disc read only memory (CD-ROM), compact disc compact disc-rewritable (CD-RW), digital versatile disc (DVD), Blu-Ray, any other non-transitory optical medium, punch cards, paper tape, optical mark sheets, any other physical medium with patterns of holes or other optically recognizable indicia, a random access memory (RAM), a programmable read only memory (PROM), an erasable programmable read only memory (EPROM), a FLASH-EPROM, any other memory chip or cartridge, a carrier wave, or any other non-transitory medium from which a computer can read. The term computer-readable storage medium is used herein to refer to any computer-readable medium except transmission media. However, it will be appreciated that where embodiments are described to use a computer-readable storage medium, other types of computer-readable mediums may be substituted for or used in addition to the computer-readable storage medium in alternative embodiments. By way of example only, a design file for a printed article may be stored on a computer-readable medium and may be read by a computing device, such as described hereinbelow, for controlling part or all of a 3D printing process and associated apparatuses and components, according to various embodiments described herein.

As used herein, the term “circuitry” refers to all of the following: (a) hardware-only circuit implementations (such as implementations in only analog and/or digital circuitry); (b) to combinations of circuits and computer program product(s) comprising software (and/or firmware instructions stored on one or more computer readable memories), such as (as applicable): (i) to a combination of processor(s) or (ii) to portions of processor(s)/software (including digital signal processor(s)), software, and memory(ies) that work together to cause an apparatus, such as a mobile phone or server, to perform various functions described herein); and (c) to circuits, such as, for example, a microprocessor(s) or a portion of a microprocessor(s), that require software or firmware for operation, even if the software or firmware is not physically present. This definition of “circuitry” applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in a server, a cellular network device, other network device, and/or other computing device.

As used herein, the term “computing device” refers to a specialized, centralized device, network, or system, comprising at least a processor and a memory device including computer program code, and configured to provide guidance or direction related to the charge transactions carried out in one or more charging networks.

As used herein, the terms “about,” “substantially,” and “approximately” generally mean plus or minus 50% of the value stated, e.g., about 200 μm would include 100 μm to 300 μm, about 1,000 μm would include 500 μm to 1,500 μm. Any provided value, whether or not it is modified by terms such as “about,” “substantially,” or “approximately,” all refer to and hereby disclose associated values or ranges of values thereabout, as described above.

As used herein, “and/or” refers to and encompasses any and all possible combinations of one or more of the associated listed items, as well as the lack of combinations when interpreted in the alternative (“or”).

As used herein, conditional language used herein, such as, among others, “can,” “could,” “might,” “may,” “e.g.,” and the like, unless specifically stated otherwise or otherwise understood within the context as used, is generally intended to convey that certain examples include, while other examples do not include, certain features, elements and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

As used herein, the terms “resin” and “monomer” may be used interchangeably. In some embodiments, a “resin” may comprise one or more of: a monomer, a photoinitiator, a photoabsorber, an inhibitor, a dye, micro/nano particles, any other component desired for polymerization or the resulting 3D object, or combinations thereof. As used herein, a “liquid resin” or a “liquid monomer” will generally be used to refer to the fluid in the containment vessel that is used to form the solid polymer and may include the components listed above for a resin and any other additional component desired for the resulting 3D object. The liquid monomer can include metal, polymer, ceramic, and/or a mixture thereof, such as organic molecules, monomer, or polymer with dispersed metal or ceramic nanoparticles. The liquid monomer may be any suitable composition to form the desired solid polymer from liquid material.

As used herein, the term “polymerization” or “curing” may refer to the process of converting liquid monomer into a “solid polymer.” The method may not be limited to creating “polymers” (e.g., “plastics”). The disclosed devices and methods may be used to create any 3D object out of any suitable materials, for example, polymers, metals, ceramics, etc., and combinations thereof. The materials may be modified to prepare the desired object from the desired material. Thus, while the reaction process (e.g., the process of converting a liquid component to a solid component) is generally referred to as polymerization and with reference to a liquid monomer, the disclosed devices and methods may be used to create any 3D object out of any suitable materials, for example, polymers, metals, ceramics, etc., and combinations thereof, and may use liquid forms of these materials and then convert such forms to solid to form the 3D object.

As used herein, the term “microcavity” may refer to any portion of any structure, surface, object, material, component, or device that is defined by an absence of material within that portion, and for which the cavity defined therein has an average or maximal dimension of between about 1 μm and about 1,000 μm. However, use of the term “cavity” herein does not necessarily indicate that the cavity is larger than about 1,000 μm or smaller than about 1 μm. Likewise, a cavity having an average dimension (e.g., diameter) of about 1,000 μm and a maximal dimension (e.g., diameter) of greater than about 1,000 μm can still be referred to herein as a “microcavity”. Further, the terms “microcavity” and “cavity” do not imply form factor, and therefore include any structure defined by the absence of material therein and having one of many different form factors. Such form factors can include a concavity, a lumen, an aperture, an opening, an orifice, a hollow, a non-zero distance between strata or laminate layers, a duct, a tube, a channel, a conical space, combinations thereof, and/or the like. For example, a “microcavity” can refer to one or more microchannels formed within a material, formed between two portions of a material, or formed between two or more different materials.

Reference may be made throughout the present disclosure to “UV light” as the light that initiates polymerization. Light may allow for spatially controlling where polymerization occurs. However, light of any wavelength (e.g., a narrow spectrum or a broad spectrum) may be used. That is, the disclosure may be applied to light of any wavelength.

As used herein, “photopolymerization” or “photopolymerize” refer to a polymerization reaction induced or catalyzed by at least light exposure.

As used herein, a “resin” may be composed of monomer, initiator, dye, photo-absorber, inhibitor, and/or loaded micro/nano particles. The “resin” is generally used to refer to the fluid in a containment vessel that is used to form the solid polymer and may include the before-mentioned components. The “initiator” is responsible for reacting with UV light to create a free-radical and start the crosslinking reaction of the monomers. The UV light spatially controls where the resin will solidify. The photo-absorbers/dyes reduce the UV light penetration depth. The initiator is generally a “photo-initiator” because UV light is needed to initiate the reaction. However, other initiators (e.g., thermal initiators) can be added to the resin composition. The polymerization reaction is generally exothermic, so the presence of a thermal initiator can also affect the polymerization process. Furthermore, other additives, e.g., nano-particles, dyes, and fillers can be added to bring additional functionality to the fabricated part (e.g., color or mechanical strength). For example, the resin can include fumed silica particles.

As used herein, “polymerization” refers to the process of converting a resin into a “solid polymer.”

As used herein, “polymer” refers to the product of a polymerization reaction in which one or more monomers are linked together.

Reference may be made throughout the present disclosure to “UV light” as the light that initiates polymerization. However, the polymerization light may be of any wavelength in the electromagnetic spectrum (e.g., from a narrow spectrum or a broad spectrum). That is, the disclosure may be applied to light of any wavelength. In certain embodiments, the polymerization light has a wavelength of about 385 nm. In certain other embodiments, the polymerization light has a wavelength of about 405 nm or 365 nm.

Microcavities, such as those described herein, have applications ranging from engineering to biology. Optical microcavities, which confine light in small volumes using resonance, may be useful in applications ranging from quantum optics to bio and chemical sensing. In the field of biomedical research, microcavity arrays may be used for cell isolation and analysis, and micro-needles may be useful in drug delivery systems. Microfluidic channels enable lab-on-a-chip applications such as cell culture, disease diagnosis, and tissue-on-chip devices. Additionally, MEMS transducers rely heavily on fabricated microcavities, and may be effective for a wide range of sensing applications, such as pressure transducers, gyroscopes, and accelerometers. MEMS devices are typically fabricated through surface or bulk micromachining, which utilizes photolithographic patterning and etching processes on common semiconductor substrates such as Si or Ge.

Flexible sensing has emerged as a prominent field in recent years as the demand for wearable biosensors has grown. However, traditional subtractive manufacturing techniques pose a challenge for the development of flexible sensors, due to material compatibility and temperature constraints. As such, new methods for the development of microstructures commonly used in MEMS sensors are necessary to develop flexible biosensors, and to successfully integrate these devices into broader flexible electronic systems.

Additive manufacturing techniques such as inkjet and 3D printing have grown in popularity for the development of flexible electronics due to their rapid prototyping capabilities. These methods are primarily utilized for the fabrication of conductive traces and electrodes, which are then combined with other fabrication techniques such as laser etching or soft lithography of flexible cavities to create the final flexible sensor. Each additional fabrication technique utilized in a device design increases manufacturing complexity and cost, which limits scalability of these techniques to low-cost, high-volume manufacturing. 3D screen printing, the process of building up three dimensional structures through successive screen printed layers, offers a unique approach to the low cost fabrication of flexible microcavities. Few examples of this approach have been demonstrated for flexible electronics, but it offers an opportunity to develop design flexibility for devices which can be directly integrated into a flexible hybrid electronics manufacturing process, reducing manufacturing complexity, while delivering fully flexible integrated systems.

Described are systems, approaches, methods, apparatuses, devices, compositions of matter, and computer program products for 3D screen printed of flexible microcavities. Described approaches are compatible with a variety of flexible inks and can be used to print geometric microcavity structures directly integrated with electronic interconnects and processing circuitry. Example flexible microfluidic channels were fabricated and tested, e.g., for use as a capacitive sensor towards sweat rate sensing.

Cavities fabricated on the microscale have a wide variety of applications, from microwells for cell cultures, to microfluidic channels for drug delivery systems, to waveguide structures for RF applications. Microcavities are particularly useful for sensing applications, such as cavity-based pressure sensors and gap-based capacitive sensors. Cavity structures have been widely demonstrated in MEMS devices using typical semiconductor processing. However, the development of similar structures for flexible applications poses additional challenges. While flexible cavity structures have been fabricated in laboratory environments, challenges arise when these structures are integrated into a larger flexible sensing device or flexible hybrid electronics system. Additive manufacturing approaches are described herein for formation of cavities (e.g., microcavities) which utilize 3D screen-printing processes. Patterned micro-structures can be formed by building up layers of dielectric ink interspersed as needed with printed conductive traces. An example microfluidic channel-based capacitor was fabricated to demonstrate the potential sensing applications for the fabricated microcavities.

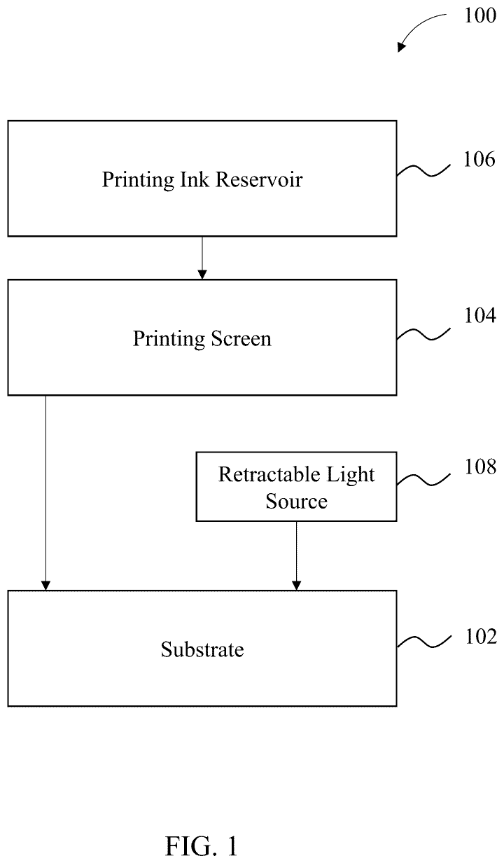

Referring now to FIG. 1, a 3D screen-printing system 100 is illustrated that includes a substrate 102 positioned beneath a printing screen 104 that is fed printing ink from a printing ink reservoir 106. When the printing ink is disposed onto or across the printing screen 104, the printing ink may be printed onto a portion of a top surface of the substrate 102 according to a pattern dictated by the configuration of the printing screen 104. The printing screen 104 can include an inverse or negative of a desired pattern to be printed in the printing ink on the top surface of the substrate 102, such as one or more apertures through the printing screen 104 that corresponds to the desired pattern to be printed in the printing ink on the top surface of the substrate 102. In some embodiments, the printing screen 104 can form a stencil that corresponds to the desired pattern to be printed in the printing ink on the top surface of the substrate 102. In some embodiments, the printing screen 104 can be formed from a screen, a mesh, a polymer, a woven material, a nonwoven material, a silkscreen, a metal, other suitable materials known to those of skill in the fields of screen printing and materials science, and combinations thereof.

In some embodiments, the printing screen 104 can be configured to allow the printing ink to be selectively communicated through a portion of the printing screen 104. In some embodiments, the printing screen 104 can be configured to allow a curing emission, such as electromagnetic radiation, to be communicated through a portion of the printing screen 104.

The 3D screen-printing system 100 can further comprise a retractable light source 108. In some embodiments, the light source 108 can be configured to generate and/or emit heat, energy, electromagnetic radiation, ultraviolet (UV) light, visible light, infrared radiation (IR), microwaves, radio waves, x-rays, other forms of energy or electromagnetic radiation, and/or combinations thereof.

During screen-printing, the retractable light source 108 can have a default position in which it is retracted. In some embodiments, this may mean that the retractable light source 108 is laterally positioned away from or to a side of the substrate 102 and/or the printing screen 104. According to some embodiments, the retractable light source 108 comprises or is mounted on rollers or a slide assembly. In some embodiments, the retractable light source 108 can comprise a plurality of portions that are configured to retract to a retracted position or extend from the retracted position to an extended position from one or more sides of the substrate 102 and/or the printing screen 104.

Once the printing ink is communicated through the printing screen 104 and disposed onto at least a portion of the top surface of the substrate 102 according to the desired pattern, the retractable light source 108 can be extended from the retracted position to the extended position. In the extended position, the retractable light source 108 can emit light, energy, heat, or the like, to cause at least partial curing, cross-linking, gelation, and/or the like of the portion of the printing ink disposed on the top of the substrate 102 according to the desired pattern associated with the printing screen 104. Once the portion of the printing ink disposed on the top of the substrate 102 according to the desired pattern associated with the printing screen 104 is cured, cross-linked, gelled, or the like, the disposed printing ink forms a first layer or portion of a 3D printed article. Thereafter, the retractable light source 108 can be transitioned from the extended position back to the retracted position to reset the 3D screen-printing system 100 for subsequent printing of other portions of the 3D printed article.

Subsequently, one or more additional layers or portions of the 3D printed article can be printed using the same or a similar approach. For example, the printing screen 104 can be used for a second and/or subsequent screen-printing iterations. In some embodiments, another printing screen (not shown) different from the printing screen 104 can be used for a second and/or subsequent screen-printing iterations.

In some embodiments, the printing screen 104 can be provided as a portion of a printing screen ribbon (not shown). The printing screen ribbon can be provided on a reel or roll and can be dispensed therefrom. The printing screen ribbon can be dispensed from a dispensing reel or a dispensing roll, across a position below the nozzle and above the substrate 102, maintained in said position during the first iteration of screen-printing onto the substrate 102, and then the printing screen 104 potion of the printing screen ribbon can be collected again on a collecting reel or a collecting roll.

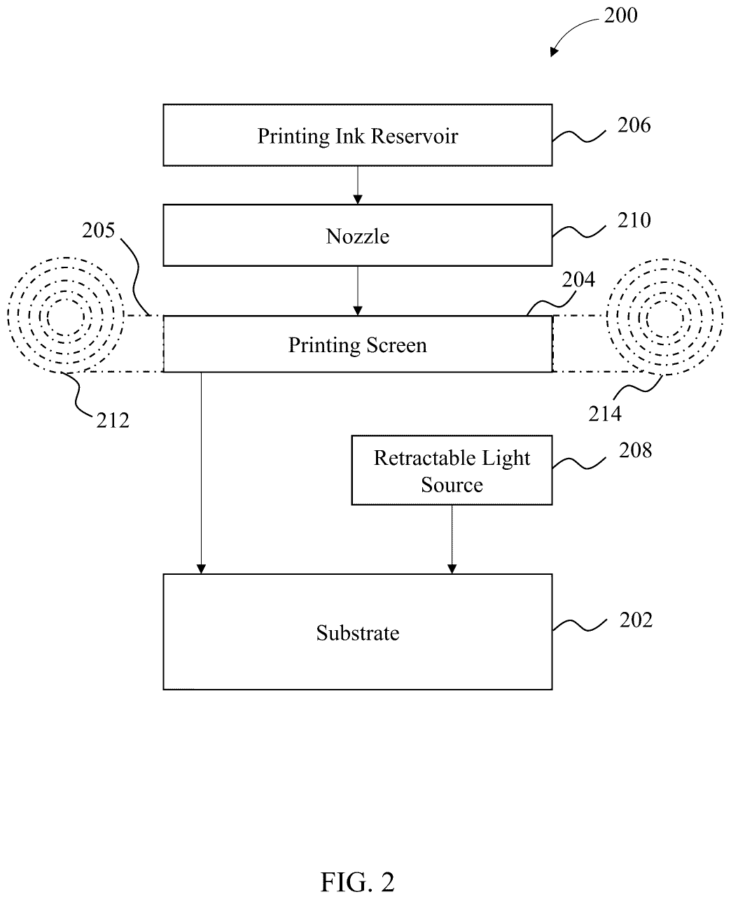

Referring now to FIG. 2, a 3D screen-printing system 200 is illustrated in which printing ink is communicated from a printing ink reservoir 206, through a nozzle 210, across and through a printing screen 210, and onto a top surface of a substrate 202. In the 3D screen-printing system 200 illustrated in FIG. 2, the printing screen 204 is provided as a portion of a printing screen ribbon 205. The printing screen ribbon 205 can be provided on a dispensing roll 212 and can be dispensed therefrom. The printing screen ribbon 205 can be dispensed from the dispensing roll 212, across a position below the nozzle 210 and above the substrate 202, maintained in said position during the first iteration of screen-printing onto the substrate 202, and then the printing screen 204 portion of the printing screen ribbon 205 can subsequently be collected again on a collecting roll 214.

The 3D screen-printing system 200 can further comprise a retractable light source 208, which can be similar to or the same as the retractable light source 108 described above with regard to FIG. 1. During screen-printing, the retractable light source 208 can have a default position in which it is retracted. In some embodiments, this may mean that the retractable light source 208 is laterally positioned away from or to a side of the substrate 202 and/or the printing screen 204. According to some embodiments, the retractable light source 208 comprises or is mounted on rollers (not shown) or a slide assembly (not shown). In some embodiments, the retractable light source 208 can comprise a plurality of portions that are configured to retract to a retracted position or extend from the retracted position to an extended position from one or more sides of the substrate 202 and/or the printing screen 204.

Once the printing ink is communicated through the printing screen 204 and disposed onto at least a portion of the top surface of the substrate 202 according to the desired pattern, the retractable light source 208 can be extended from the retracted position to the extended position. In the extended position, the retractable light source 208 can emit light, energy, heat, or the like, to cause at least partial curing, cross-linking, gelation, and/or the like of the portion of the printing ink disposed on the top of the substrate 202 according to the desired pattern associated with the printing screen 204. Once the portion of the printing ink disposed on the top of the substrate 202 according to the desired pattern associated with the printing screen 204 is partially cured, cured, partially cross-linked, cross-linked, partially gelled, gelled, or the like, the disposed printing ink forms a first layer or portion of a 3D printed article. Thereafter, the retractable light source 208 can be transitioned from the extended position back to the retracted position to reset the 3D screen-printing system 200 for subsequent printing of other portions of the 3D printed article.

Subsequently, one or more additional layers or portions of the 3D printed article can be printed using the same or a similar approach. For example, the printing screen 204 can be used for a second and/or subsequent screen-printing iterations. In some embodiments, another printing screen (not shown) different from the printing screen 204 can be used for a second and/or subsequent screen-printing iterations. In some embodiments, the another printing screen different from the printing screen 204 is adjacent on the printing screen ribbon 205 to the printing screen 204.

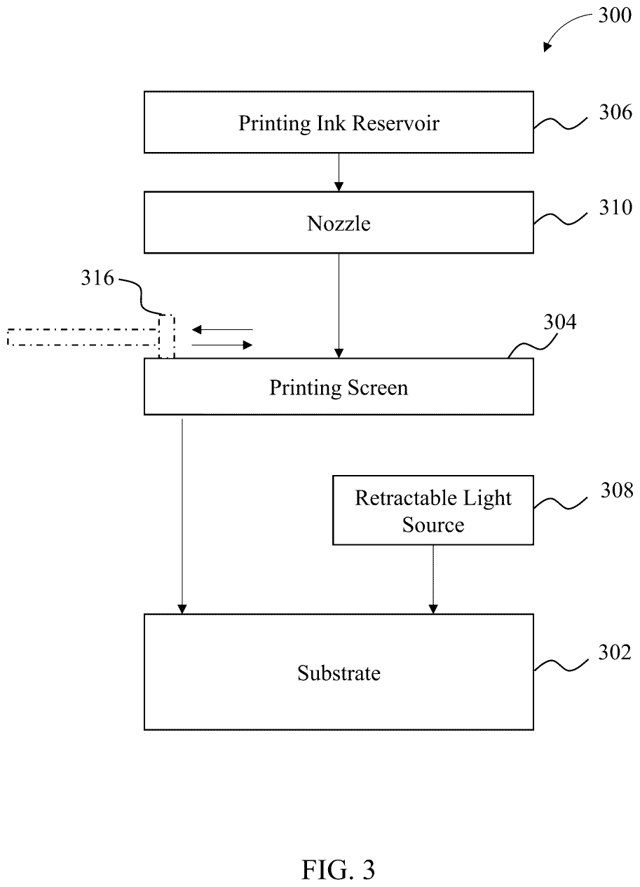

Referring now to FIG. 3, a 3D screen-printing system 300 is illustrated in which printing ink is communicated from a printing ink reservoir 306, through a nozzle 310, and onto a printing screen 304. The 3D screen-printing system 300 further comprises a squeegee 316 that is configured to spread the printing ink across the printing screen 304 after the printing ink is dispensed from the nozzle 310 and onto a top surface of the printing screen 304. The squeegee 316 can be dimensioned and configured to contact, partially contact, selectively contact, and/or nearly contact the top surface of the printing screen 304. For example, the squeegee 316 can include a contacting surface or a contacting edge that is configured to contact, selectively contact, and/or nearly contact the top surface of the printing screen 304. The contacting surface or contacting edge of the squeegee 316 can comprise an edge, such as a bar, flood bar, blade, sluice, fin, inclined plane, inclined plane, wedge, sluice, other suitable structures and form factors, and/or combinations thereof.

In other embodiments, the squeegee 316 can be dimensioned and configured to be spaced a non-zero distance above the top surface of the printing screen 304. In other embodiments, the squeegee 316 can be dimensioned and configured to be spaced multiple non-zero distances above the top surface of the printing screen 304, e.g., as the squeegee 316 is moved over or across the top surface of the printing screen 304. In still other embodiments, the squeegee 316 can be dimensioned and configured to be spaced a first non-zero distance above the top surface of the printing screen 304 at a first time or during a first time period and then, as the squeegee 316 is moved over the surface of the printing screen 304, the squeegee 316 can be configured to move to a second non-zero distance above the top surface of the printing screen 304. In other embodiments, the squeegee 316 can be dimensioned and configured to be spaced one of a plurality of non-zero distances above the top surface of the printing screen 304, where the actual non-zero distance at which the squeegee 316 is spaced above the top surface of the printing screen 304 can be varied based on, e.g., a predetermining design, preconfigured operational commands, local feedback about one or more conditions or characteristics at or on the printing screen 304, local feedback such as sensor feedback at or nearby the squeegee 316, and/or the like.

For example, according to one or more embodiments, the non-zero distance of the squeegee 316 above the top surface of the printing screen 304 can be controlled, at least in part, by a computing device or the like, and the computing device can send commands or signals to the squeegee 316 or a squeegee positional control system (not shown) that controls one or more movements, locations, positions, or proximities of the squeegee 316 relative to the top surface of the printing screen 304. The squeegee positional control system can further comprise a sensor (not shown) that is configured to determine a magnitude of the non-zero distance of the squeegee 316 above the top surface of the printing screen 304.

In some embodiments, the squeegee positional control system can further comprise a motor (not shown) or the like that is configured to at least partially cause movement of the squeegee 316 over or across the top surface of the printing screen 304. In some embodiments, this motor may be controlled at least in part by the computing device or the like that at least partially controls one or more movements of the squeegee 316 relative to the top surface of the printing screen 304. In some embodiments, one or more characteristics or operational parameters of the motor (such as motor strain) can be monitored to determine whether the squeegee 316 is moving the printing ink over the top surface of the printing screen 304 and/or a depth of that printing ink on the top surface of the printing screen 304 as the squeegee 316 pushes or spreads at least some of the printing ink as it moves over or across the top surface of the printing screen 304.

In some embodiments, at least a portion of the bottom surface of the printing screen 304 can be placed into contact with at least a portion of the top surface of the substrate 302 or cross-linked structures/layers previously screen-printed onto the top surface of the substrate 302 before the cross-linkable printing ink is disposed onto at least a portion of the top surface of the printing screen 304. In other embodiments, at least a portion of the bottom surface of the printing screen 304 can be placed into contact with at least a portion of the top surface of the substrate 302 or cross-linked structures/layers previously screen-printed onto the top surface of the substrate 302 only after the cross-linkable printing ink is disposed onto at least a portion of the top surface of the printing screen 304.

The squeegee 316 can comprise or be operably coupled to a reciprocating element or the like that is configured to move the contacting surface or contacting edge of the squeegee 316 across the top surface of the printing screen 304 in order to evenly spread the cross-linkable printing ink over said at least a portion of the printing screen 304. In some embodiments, merely disposing the cross-linkable printing ink onto the top surface of the printing screen 304 may not cause the cross-linkable printing ink to be communicated through the portions of the printing screen 304 that are permeable to the cross-linkable printing ink, while in other embodiments the printing screen 304 may allow at least partial communication of the cross-linkable printing ink through the portions of the printing screen 304 that are permeable to the cross-linkable printing ink.

In some embodiments, the movement of the squeegee 316 or a portion thereof across the top surface of the printing screen 304 may cause at least partial communication of the cross-linkable printing ink through the portions of the printing screen 304 that are permeable to the cross-linkable printing ink. In other embodiments, the movement of the squeegee 316 or a portion thereof across the top surface of the printing screen 304 may not cause at least partial communication of the cross-linkable printing ink through the portions of the printing screen 304 that are permeable to the cross-linkable printing ink but instead may merely cause the cross-linkable printing ink to be more evenly spread across the top surface of the printing screen 304. In some embodiments, direct contact of the top surface of the substrate 302 against the bottom surface of the printing screen 304 may cause or facilitate at least partial communication of the cross-linkable printing ink through the portions of the printing screen 304 that are permeable to the cross-linkable printing ink and onto the top surface of the substrate 302. In some embodiments, direct contact of the bottom surface of the printing screen 304 against the top surface of the substrate 102 may cause or facilitate at least partial communication of the cross-linkable printing ink through the portions of the printing screen 304 that are permeable to the cross-linkable printing ink and onto the top surface of the substrate 302. In other embodiments, it may require a compressive force, such as a compressive force of the contacting edge or contacting surface of the squeegee 316 against the top surface of the printing screen 304, above a particular threshold (e.g., a cross-linkable printing ink-specific threshold and/or a printing screen-specific threshold) for the cross-linkable printing ink to at least partially be communicated through the portions of the printing screen 304 that are permeable to the cross-linkable printing ink and onto the top surface of the substrate 302.

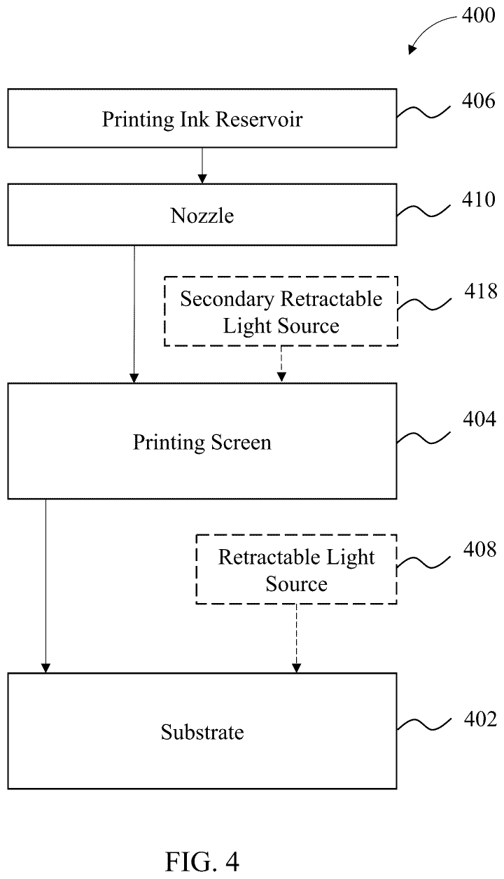

Referring now to FIG. 4, a 3D screen-printing system 400 is illustrated which comprises a substrate 402 positioned beneath a printing screen 404 that is fed printing ink from a printing ink reservoir 406. When the printing ink is disposed onto or across the printing screen 404, the printing ink may be printed onto a portion of a top surface of the substrate 402 according to a pattern dictated by the configuration of the printing screen 404. The printing screen 404 can include an inverse or negative of a desired pattern to be printed in the printing ink on the top surface of the substrate 402, such as one or more apertures through the printing screen 404 that corresponds to the desired pattern to be printed in the printing ink on the top surface of the substrate 402. In some embodiments, the printing screen 404 can form a stencil that corresponds to the desired pattern to be printed in the printing ink on the top surface of the substrate 402. In some embodiments, the printing screen 404 can be formed from a screen, a mesh, a polymer, a woven material, a nonwoven material, a silkscreen, a metal, other suitable materials known to those of skill in the fields of screen printing and materials science, and combinations thereof.

In some embodiments, the printing screen 404 can be configured to allow the printing ink to be selectively communicated through a portion of the printing screen 404. In some embodiments, the printing screen 404 can be configured to allow a curing emission, such as electromagnetic radiation, to be communicated through a portion of the printing screen 404.

The 3D screen-printing system 1400 can further comprise a retractable light source 408. In some embodiments, the light source 408 can be configured to generate and/or emit heat, energy, electromagnetic radiation, ultraviolet (UV) light, visible light, infrared radiation (IR), microwaves, radio waves, x-rays, other forms of energy or electromagnetic radiation, and/or combinations thereof.

During screen-printing, the retractable light source 408 can have a default position in which it is retracted. In some embodiments, this may mean that the retractable light source 408 is laterally positioned away from or to a side of the substrate 402 and/or the printing screen 404. According to some embodiments, the retractable light source 408 comprises or is mounted on rollers or a slide assembly. In some embodiments, the retractable light source 408 can comprise a plurality of portions that are configured to retract to a retracted position or extend from the retracted position to an extended position from one or more sides of the substrate 402 and/or the printing screen 404.

Once the printing ink is communicated through the printing screen 404 and disposed onto at least a portion of the top surface of the substrate 402 according to the desired pattern, the retractable light source 408 can be extended from the retracted position to the extended position. In the extended position, the retractable light source 408 can emit light, energy, heat, or the like, to cause at least partial curing, cross-linking, gelation, and/or the like of the portion of the printing ink disposed on the top of the substrate 402 according to the desired pattern associated with the printing screen 404. Once the portion of the printing ink disposed on the top of the substrate 402 according to the desired pattern associated with the printing screen 404 is cured, cross-linked, gelled, or the like, the disposed printing ink forms a first layer or portion of a 3D printed article. Thereafter, the retractable light source 408 can be transitioned from the extended position back to the retracted position to reset the 3D screen-printing system 400 for subsequent printing of other portions of the 3D printed article.

Subsequently, one or more additional layers or portions of the 3D printed article can be printed using the same or a similar approach. For example, the printing screen 404 can be used for a second and/or subsequent screen-printing iterations. In some embodiments, another printing screen (not shown) different from the printing screen 404 can be used for a second and/or subsequent screen-printing iterations.

In some embodiments, the printing screen 404 can be provided as a portion of a printing screen ribbon (not shown). The printing screen ribbon can be provided on a reel or roll and can be dispensed therefrom. The printing screen ribbon can be dispensed from a dispensing reel or a dispensing roll, across a position below the nozzle and above the substrate 402, maintained in said position during the first iteration of screen-printing onto the substrate 402, and then the printing screen 404 potion of the printing screen ribbon can be collected again on a collecting reel or a collecting roll.

In some embodiments, the 3D screen-printing system 400 can, optionally, further comprise a secondary retractable light source 418. In some embodiments, the 3D screen-printing system 400 can, optionally, comprise the retractable light source 408 in addition to the secondary retractable light source 418. In other embodiments, the 3D screen-printing system 400 can, optionally, comprise the secondary retractable light source 418 instead of the retractable light source 408.

As illustrated in FIG. 4, the secondary retractable light source 418 is dimensioned and configured to be selectively positioned between the nozzle 410 and the top surface of the printing screen 404. This may facilitate, among other things, the selective curing of only parts of a portion of cross-linkable printing ink previously screen-printed onto the substrate 402, such as by the selective occlusion of the curing means (e.g., UV light, heat, etc.) emitted from the secondary retractable light source 418. This can be carried out by providing a curing screen (not shown) that, rather than being cross-linkable printing ink permeable, is configured to allow UV light, heat, or the like to be communicated through portions of the curing screen, according to a desired curing pattern. This may be useful when it is undesirable for cross-linkable printing ink previously screen-printed onto the substrate 402 and previously cured/cross-linked to be exposed to further curing means (e.g., UV light), such as when emitted UV light from the retractable light source 408 would not be spatially occluded in any way.

Just as with the retractable light source 408, during screen-printing, the secondary retractable light source 418 can have a default position in which it is retracted. In some embodiments, this may mean that the secondary retractable light source 418 is laterally positioned away from or to a side of the substrate 402, the printing screen 404, and/or the curing screen. According to some embodiments, the secondary retractable light source 418 comprises or is mounted on rollers (not shown) or a slide assembly (not shown). In some embodiments, the secondary retractable light source 418 can comprise a plurality of portions that are configured to retract to a retracted position or extend from the retracted position to an extended position from one or more sides of the substrate 402, the printing screen 404, and/or the curing screen.

Once the printing ink is communicated through the printing screen 404 and disposed onto at least a portion of the top surface of the substrate 402 according to the desired pattern, another printing screen (not shown), mask (not shown) and/or a curing screen (not shown) can replace the printing screen 404 used in screen-printing of the cross-linkable printing ink onto the top surface of the substrate 402. Thereafter, the secondary retractable light source 418 can be extended from the retracted position to the extended position. In the extended position, the secondary retractable light source 418 can emit light, energy, heat, or the like, to cause at least partial curing, cross-linking, gelation, and/or the like of the portion of the printing ink disposed on the top of the substrate 402. In some embodiments, the amount of curing can be controlled by changing a duration of curing, an intensity of UV light or heat emitted, a distance at which the UV light or heat is emitted, other suitable means, and/or combinations thereof. In some embodiments, a spatial extent of curing of the screen-printed cross-linkable printing ink on the top surface of the substrate 402 can be controlled by changing an occlusion pattern of the curing screen/mask disposed between the secondary retractable light source 418 and the substrate 402 after screen-printing of the cross-linkable printing ink onto the top surface of the substrate 402. Once the portion of the cross-linkable printing ink disposed on the top of the substrate 402 according to the desired pattern associated with the printing screen 404 is cured, cross-linked, gelled, or the like, the disposed cross-linkable printing ink forms a first layer or portion of a 3D printed article. Thereafter, the secondary retractable light source 418 can be transitioned from the extended position back to the retracted position to reset the 3D screen-printing system 400 for subsequent printing of other portions of the 3D printed article.

Subsequently, one or more additional layers or portions of the 3D printed article can be printed using the same or a similar approach. For example, the printing screen 404 can be used for a second and/or subsequent screen-printing iterations. In some embodiments, another printing screen (not shown) different from the printing screen 404 can be used for a second and/or subsequent screen-printing iterations. In some embodiments, the another printing screen is adjacent to the printing screen 404 on a printing screen ribbon, such as the printing screen ribbon 205 shown in FIG. 2.

According to an embodiment, a fully screen-printed process can be carried out using a 4D screen-printing system, such as those illustrated in FIGS. 1-4. A fully screen-printed process may enable the fabrication of cavity structures on the micrometer scale which can be integrated into screen printed electronic circuit boards on flexible substrates to realize multi-functional flexible hybrid electronics. Such a process extends the usual screen-printing process for printed circuit boards used to pattern conducting layers and dielectric layers on a substrate into a general method that can be used to create arbitrary microcavities and conducting and dielectric layers. Cavity structures are necessary structures for any sensor, actuator, microfluidic device, or diagnostic components which requires the formation of a hollow region that may or may not need to be capped with sealing layer. By allowing the fabrication of cavity structures such as sensors, actuators, microfluidics, and diagnostic components on the micrometer scale and the patterning of conducting layers and dielectric layers on the same flexible substrate, integrated multi-functional hybrid electronics may be realized in a low-cost and high-volume screen-printing platform.

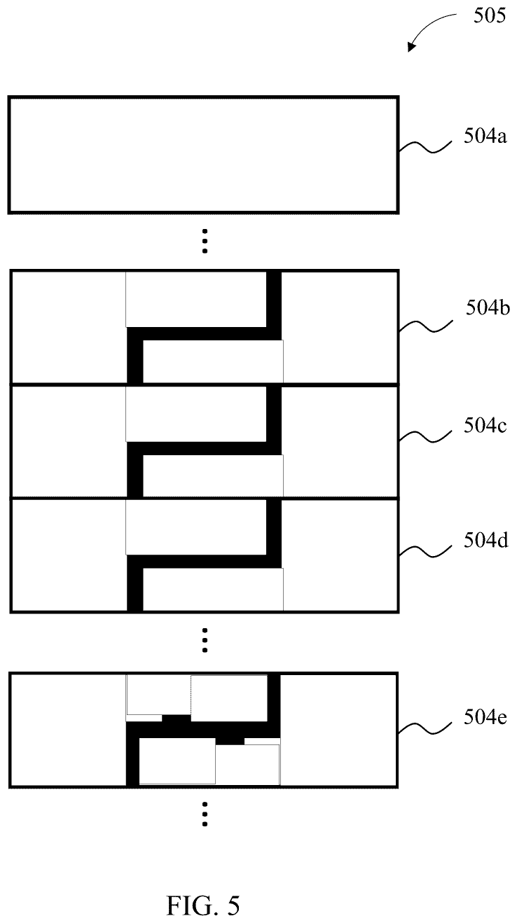

Referring now to FIG. 5, an example of a printing screen ribbon 505 is illustrated that includes a plurality of printing screens 504a-504e aligned longitudinally along a length of the printing screen ribbon 505. The plurality of printing screens 504a-504e is shown in FIG. 5 with ellipses (as “ . . . ”) between a first printing screen 504a and a second printing screen 504b as well as between a fourth printing screen 504d and a fifth printing screen 504e to illustrate that one or more additional printing screens can, respectively, be positioned therebetween. As illustrated, the white portion within each printing screen reflects the portion of printing screen that is permeable to the cross-linkable printing ink.

In the particular embodiment of FIG. 5, the first printing screen 504a of the printing screen ribbon 505 is entirely permeable to the cross-linkable printing ink, such that an even or nearly even layer of the cross-linkable printing ink will be disposed on the top surface of a substrate (e.g., 102) during a first screen printing step using the first printing screen 504a. Then, during a subsequent screen printing step using the second printing screen 504b, the two white portions of the second printing screen 504b are permeable to the cross-linkable printing ink while the black portion therebetween is impermeable to the cross-linkable printing ink, such that the cross-linkable printing ink will be disposed only on the portions of the top surface of the substrate (e.g., 102) that correspond spatially to the two white portions of the second printing screen 504b during the subsequent screen printing step, resulting in the formation of raised portions at a right end and left end of the top surface of the substrate (e.g., 102) that correspond dimensionally and in form factor to the two white portions of the second printing screen 504b, while with a slightly depressed channel is formed between the two raised portions at the right and left ends of the top surface of the substrate (e.g., 102) that corresponds to the black portion of the second printing screen 504b.

This approach of using a printing screen that is selectively spatially permeable to cross-linkable printing ink to form features having a height on the top surface of the substrate (e.g., 102) can be carried out by iterative printing. An example of this is shown in FIG. 5, in which the third printing screen 504c and fourth printing screen 504d are identical or nearly identical to the second printing screen 504b. While the same printing screen (e.g., 504b) can be used in some embodiments to simply reprint another portion of the cross-linkable printing ink onto a previously screen-printed portion of the cross-linkable printing ink after curing of the first portion, there may be slight differences or changes desired between different iterations of screen printing which may necessitate slightly different, or very different (e.g., the fifth printing screen 504e), printing screen designs be used between different screen-printing iterations. In other embodiments, such as when the printing screen ribbon 505 is used in a continuous or semi-continuous 3D screen-printing process, the use of identical or nearly identical printing screens (e.g., 504b, 504c, 504d) respectively adjacent each to another may be helpful in terms of properly timing and organizing the layout of the printing screen ribbon 505 relative to the desired structure/microcavity being 3D screen-printed.

By placing printing screens 504b, 504c, 504d ahead of printing screen 504e, the resulting microcavity structure printed will begin at a lowest point (nearest to the substrate, e.g., 102) with a uniform or nearly uniform channel structure, and a widened cavity midway along the uniform channel structure will be formed thereafter, at higher points (further from the substrate, e.g., 102) based upon the selective occlusion of cross-linkable printing ink from portions of the printing screen adjacent to the outer wall of the uniform channel structure.

In some embodiments, a width of the black portion (occlusion portion) of the second printing screen 504b may be smaller than the width of the black portion of the third printing screen 504c, which may be smaller than the width of the black portion of the fourth printing screen 504d, such that from a cross-sectional perspective, the channel structure of the microcavity formed on the substrate has a concave form factor (widening as the iterative screen-printed layers move further away from the substrate, e.g., 102). In other embodiments, the width of the black portion (occlusion portion) of the second printing screen 504b may be larger than the width of the black portion of the third printing screen 504c, which may be larger than the width of the black portion of the fourth printing screen 504d, such that from a cross-sectional perspective, the channel structure of the microcavity formed on the substrate has a convex form factor (narrowing as the iterative screen-printed layers move further away from the substrate, e.g., 102). Still other designs and form factors are contemplated and can be achieved by organizing different iterative printing screen designs to achieve a layer-by-layer approach for 3D screen-printing of structures, such as microcavities or microchannels, on the substrate (e.g., 102).

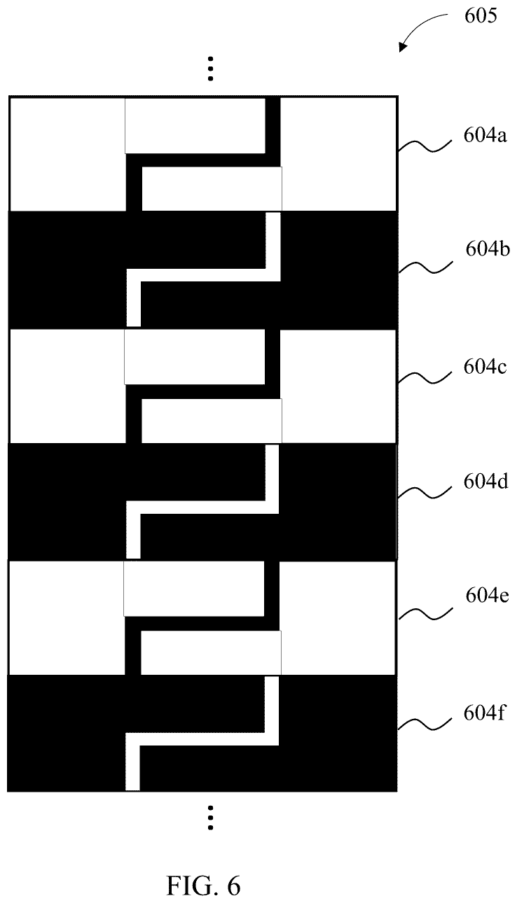

Referring now to FIG. 6, an alternative embodiment of a printing screen ribbon 605 is illustrated that includes a second plurality of printing screens 604a-604f aligned longitudinally along a length of the printing screen ribbon 605. The plurality of printing screens 604a-604f includes a first printing screen 604a, a second printing screen 604b, a third printing screen 604c, a fourth printing screen 604d, a seventh printing screen 604e, and an eighth printing screen 604f. As illustrated in FIG. 6, a white portion within each of the pluralities of printing screens 604a-694f reflects the portion that is permeable to a cross-linkable printing ink.

In the particular embodiment of FIG. 6, the first printing screen 604a of the printing screen ribbon 505 includes two white portions that are permeable to the cross-linkable printing ink while the black portion therebetween is impermeable to the cross-linkable printing ink, such that the cross-linkable printing ink will be disposed only on the portions of the top surface of a substrate, e.g., 102, that corresponds spatially to the two white portions of the first printing screen 604a during an associated screen printing step, resulting in the formation of raised portions at a right end and left end of the top surface of the substrate, e.g., 102, that correspond dimensionally and in form factor to the two white portions of the first printing screen 604a, while with a slightly depressed channel is formed between the two raised portions at the right and left ends of the top surface of the substrate (e.g., 102) that corresponds to the black portion of the first printing screen 604a. The occlusion/permeability design or pattern of the third printing screen 604c and fifth printing screen 604e of the printing screen ribbon 605 illustrated in FIG. 6 may be identical or nearly identical to that of the first printing screen 604a.

However, the occlusion/permeability design or pattern of the second printing screen 604b, the third printing screen 604d, and the fifth printing screen 604f of the printing screen ribbon 605 may be different from that in printing screens 604a, 604c, 604e. In some embodiments, the occlusion/permeability design or pattern of printing screens 604b, 604d, 604f may be a complete inverse, or nearly a complete inverse, of the occlusion/permeability design or pattern of printing screens 604a, 604c, 604e.

For example, as illustrated in FIG. 6, printing screens 604a, 604c, 604e may define a microcavity/microchannel through the middle of a raised structure by including a white portion (permeable to cross-linkable printing ink) that defines a printing region at each end of the printing screen, and further including a black portion between the two white portions that occludes printing in the black region based on an impermeability of the black portion of the printing screens 604a, 604c, 604e to the cross-linkable printing ink. Printing screens 604b, 604d, 604f may fill the microcavity/microchannel defined through the middle of the two raised structure by including a black portion (impermeable to cross-linkable printing ink) that defines an occlusion region at each end of the printing screen, and further including a white portion between the two black portions that defines a printing region in the white region based on the permeability of the white portion of the printing screens 604b, 604d, 604f to the cross-linkable printing ink. In some embodiments, a first cross-linkable printing ink may be used when screen-printing using the printing screens 604a, 604c, 604e, while a second material, such as a second cross-linkable printing ink, may be used when screen-printing using the printing screens 604b, 604d, 604f. This may be useful in scenarios in which a microchannel or microcavity is to be initially formed using a sacrificial material that is to be later removed, such as by diluting, dissolving, or otherwise removing the sacrificial material.

In other embodiments, such as when the 3D screen-printing system 400 illustrated in FIG. 4 is used, select of the iterative printing screens may include regions that are permeable to, or occlusive of, the cross-linkable printing ink, while other of the iterative printing screens may include regions that are permeable to, or occlusive of, cross-linking means, such as UV light. For example, printing screens 604a, 604c, 604e may be used to define a microcavity/microchannel through the middle of a raised structure by including white portions (permeable to cross-linkable printing ink) that defines a printing region at each end of the printing screen, and may further include a black portion between the two white portions that occludes printing in the black region based on an impermeability of the black portion of the printing screens 604a, 604c, 604e to the cross-linkable printing ink. However, printing screens 604b, 604d, 604f may include two black regions at each end of the printing screen that are permeable to UV light, for example, while the white region defined between the two black regions are occlusive of UV light, meaning that excessive UV light is not emitted towards any already-crosslinked printing ink that is disposed on the substrate (e.g., 102) beneath the white region (e.g., an initially printed layer that defines a bottom of the microchannel/microcavity).

This approach of using screen-printing screens that are selectively spatially permeable to cross-linkable printing ink and/or UV light or the like to form features having a height on the top surface of the substrate (e.g., 102) can be carried out by iterative printing and curing/cross-linking. In some embodiments, by placing printing screens 604b, 604d, 604f immediately after, respectively, printing screens 604a, 604c, 604e, each layer of the resulting microcavity/microchannel structure being printed will be printed, immediately cured/cross-linked, and then will form a solid structure/layer upon which the subsequent layer of cross-linkable printing ink may be printed.

Many designs and form factors are contemplated and can be achieved by organizing different iterative printing screen designs and UV light occlusion designs to achieve a layer-by-layer approach for 3D screen-printing of structures, such as microcavities or microchannels, on the substrate 102.

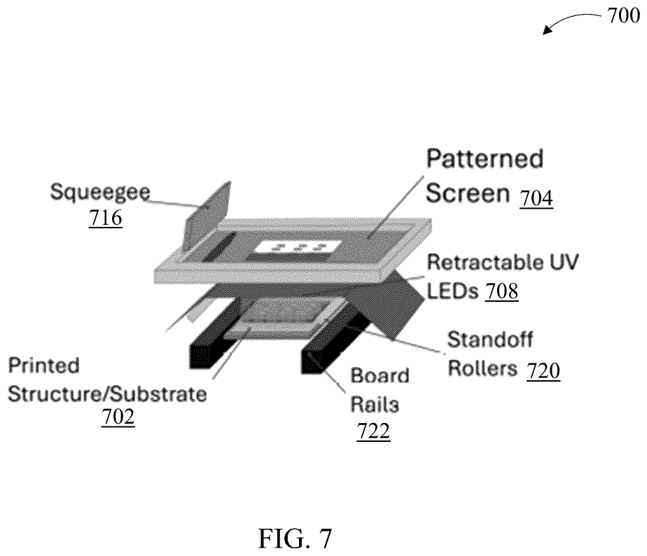

Referring now to FIG. 7, a 3D screen-printing system 700 is illustrated that is configured for forming patterned micro-structures by building up layers of ultra-violet (UV) curable dielectric ink, in conjunction with printed conductive traces. The structures are then capped using a thermal lamination film. Using the 3D screen-printing system 700, additional screen-printed layers can be built up on top of this laminated capping layer to complete the device structure.

Prior to screen-printing, a substrate, e.g., a polyethylene terephthalate (PET) substrate, is prepared by cleaning a top surface of the substrate, e.g., with isopropyl alcohol, to remove environmental contaminants. In some embodiments, a graphic layer can be initially screen-printed onto the substrate to create fiducial markings that may be used during a subsequent layer alignment process, as well as any additional markings needed for the specific device fabrication. Final substrate preparation, including the cutting of any vias or screen printing of conductive electrodes is then completed.

In some embodiments, the 3D screen-printing system 700 is configured such that the first dielectric ink layer is deposited using a stainless-steel mesh screen patterned with the cavity geometry. The 3D screen-printing system 700 can be configured to emit UV light to cure screen-printed cross-linkable printing ink. The 3D screen-printing system 700 can include a UV light emitting diode (LED) setup. The 3D screen-printing system 700 can be configured such that the steps of screen-printing and subsequent UV light curing are iteratively repeated until the desired cavity height is reached. This desired cavity height may be determined by a thickness of a single dielectric printed layer, or otherwise determined based upon the application/device for which the microcavity/microchannel is being formed.

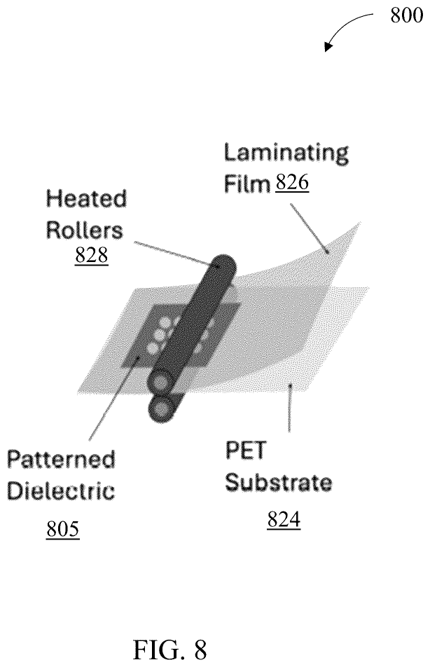

In some embodiments, the 3D screen-printing system 700 can be configured to dispense a film cap onto or over a defined/formed microcavity or microchannel. For example, the 3D screen-printing system 700 can be configured such that a thermal PET film is adhered to a top of a patterned microcavity/microchannel. The 3D screen-printing system 700 may comprise a heated laminating roller press 800, such as that illustrated in FIG. 8, that is configured to dispense a suitable film, such as a thermal PET film. When heated and disposed over or rolled across the printed microcavity/microchannel, a thermal PET film or the like will adhere to the top of the printed structures that stand proud of the substrate (e.g., 102), thereby forming the patterned microcavity/microchannel. Once adhered to the printed structures/layers that stand proud of the substrate (e.g., 102), the thermal PET film, or the like, can form a flat capping layer that encapsulates the microcavity/microchannel.

In some embodiments, the 3D screen-printing system 700 can be configured to screen-print additional elements/features on top of the flat capping layer. By first adhering the thermal PET film or the like over the printed structures that stand proud of the substrate and form the patterned microcavity/microchannel, the resulting flat capping layer may encapsulate the microcavity/microchannel such that additional features can be printed on top of/over the microcavity/microchannel. For example, additional device elements can be screen printed on top of the film to complete the devices and integrate them into the surrounding electronics.

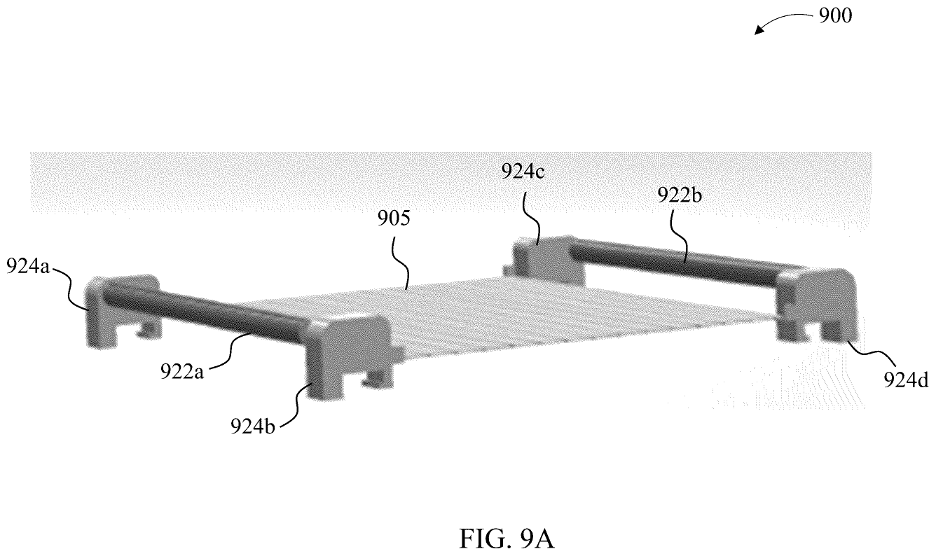

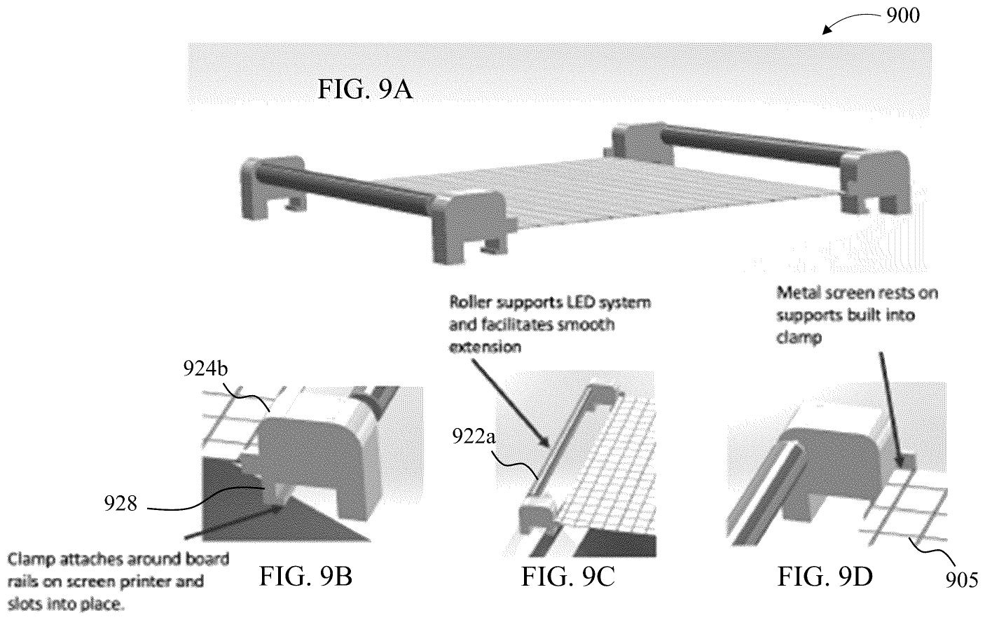

FIG. 9A-9B illustrates at least a portion of a screen-printing system 900 that comprises a substrate support 902 disposed between a first roller 922a and a second roller 922b. The first and second rollers 922a, 922b can comprise or be positioned nearby one or more light emitting elements or light generating elements (not shown), such as light-emitting diodes (LEDs). In some embodiments, the first roller 922a can be held in place using at least a first roller support 924a and a second roller support 924b. In some embodiments, the second roller 922b can be held in place using at least a third roller support 924c and a fourth roller support 924d. The screen-printing system 900 can be dimensioned and configured to perform screen printing of a printing ink onto a substrate (not shown), such as a dielectric substrate. The substrate can be supported on the substrate support 902 between the first and second rollers 922a, 922b.

During screen-printing, a printing mask (not shown) or the like can be moved between the first roller 922a and the second roller 922b. For example, the printing mask can be initially wound about the first roller 922a and, during screen printing, the printing mask can be dispensed from the first roller 922a by unwinding the first roller 922a, and the printing mask can be moved across the substrate supported on the substrate support 902 and wound about the second roller 922b. As the printing mask is moved across the substrate supported on the substrate support 902, a printing ink can be spread over at least a portion of the printing mask to cause selective disposition of the printing ink onto the substrate. In some embodiments, this screen-printing process can be carried out in a continuous or semi-continuous manner. In other embodiments, this screen-printing process can be carried out in a stage-wise or discontinuous manner.

In some embodiments, the first roller 922a can be unwound a predetermined amount to advance the printing mask across the substrate supported on the substrate support 902 and then a leading edge or a leading portion of the printing mask can be rotationally received by or onto the second roller 922b. Thereafter, rotation of the first and second rollers 922a, 922b can be stopped, thereby stopping further advancement of the printing mask between the first roller 922a and the second roller 922b. Then, after stopping further advancement of the printing mask between the first roller 922a and the second roller 922b, a volume of printing ink can be disposed onto a top surface of the printing mask and spread across the exposed portion of the printing mask exposed between the first and second rollers 922a, 922b and supported above the substrate supported on or by the substrate support 902. Spreading the printing ink over or onto the printing mask can be performed using, spreading means (not shown), such as a squeegee, a third roller, a wiper, a scraper, a blade, an arm, a knife, a sponge, and/or the like.

In other embodiments, printing ink can be disposed onto the printing mask as a first portion of the printing mask is unwound from the first roller 922a, moved across the substrate supported on or by the substrate support 902, and round onto the second roller 922b. For example, the Then, once the first portion of the printing mask is fully exposed on or above the substrate supported on or by the substrate support 902 between the first and second rollers 922a, 922b, the printing ink, which was disposed onto the exposed portion of the printing mask as the printing mask was unwound from about the first roller 922a, can then selectively permeate (e.g., be allowed to selectively permeate, be caused to selectively permeate, etc.) through the printing ink and onto the substrate. The selective permeation of the printing ink through the printing mask can be based upon a particular design of the portion of the printing mask exposed on or above the substrate supported on or by the substrate support 902 between the first and second rollers 922a, 922b.

In some embodiments, once the printing ink is disposed onto the portion of the printing mask exposed on or above the substrate supported on or by the substrate support 902 between the first and second rollers 922a, 922b, the printing ink can be allowed or caused to permeate through one or more apertures through the printing mask. In some embodiments, permeation of the printing ink through the one or more apertures through the exposed portion of the printing mask can be fully affected without further intervention (e.g., based on one or more of gravity, surface tension, interfacial tension, absorption/adsorption, capillarity/capillary action, and/or the like). In other embodiments, permeation of the printing ink through the one or more apertures through the printing mask can be facilitated or expedited using one or more of the spreading means, such as a squeegee, a third roller, a wiper, a scraper, a blade, an arm, a knife, a sponge, and/or the like.

In some embodiments, the rollers 922a, 922b can be configured to dispense and/or receive a printing screen (e.g., 204) over or across the substrate 902. In some embodiments, one or more of the roller supports 924a, 924b, 924c, and/or 924d of the screen-printing system 900 can comprise or define a clamp 928 that is configured to retain therein an edge portion of the substrate support 902 dimensioned and configured to support thereon the substrate. In some embodiments, the substrate support 902 can be or comprise a plate, a sheet, a mesh, and/or the like. In some embodiments, the substrate support 902 can be or comprise a metal material, a ceramic material, a polymeric material, a natural material, or the like. In some embodiments, the substrate support 902 can be sufficiently durable to withstand the forces exerted on the substrate support 902 during screen-printing (e.g., disposing the substrate on the substrate support 902, moving the printing mask across the substrate supported on the substrate support 902, spreading printing ink onto the printing mask, etc.).

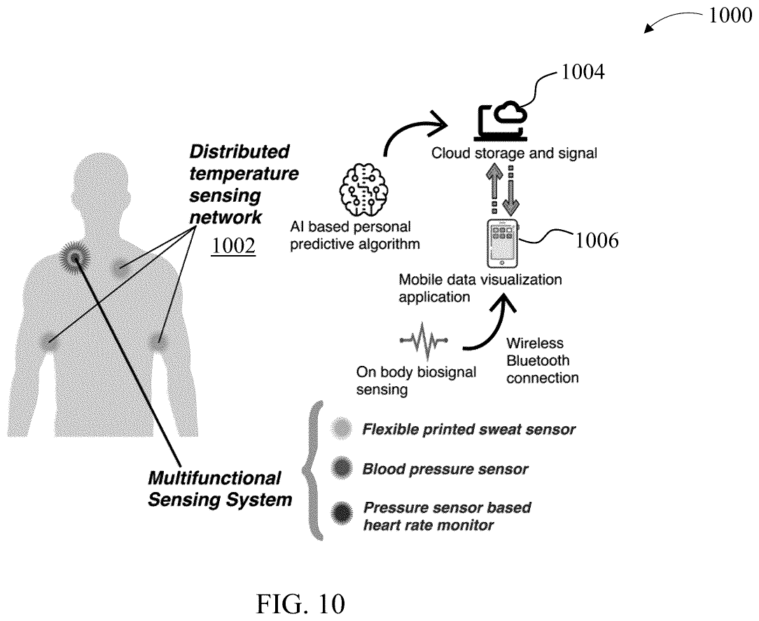

FIG. 10 illustrates a system 1000 for sensing using integrated flexible sensors and processing circuitry. The system 1000 can comprise a distributed sensor network 1002. The distributed sensor network 1002 can comprise one or a plurality of distributed sensors. The distributed sensor network 1002 can comprise one or a plurality of different types of sensors.

In some embodiments, the distributed sensor network 1002 can comprise one or more sweat sensors, one or more blood pressure sensors, one or more heart rate sensors, one or more blood oxygen sensors, one or more biosensors, one or more optical sensors, one or more pressure sensors, one or more electrochemical sensors, one or more potentiometric sensors, one or more force sensors, one or more stress sensors, one or more strain sensors, one or more magnetic sensors, one or more electromagnetic sensors, one or more piezoelectric sensors, one or more amperometry sensors, one or more electrical sensors, one or more temperature sensors, one or more humidity sensors, one or more light sensors, one or more radiation sensors, one or more touch sensors, one or more displacement sensors, one or more motion sensors, one or more position sensors, one or more proximity sensors, one or more accelerometers, one or more vibration sensors, one or more gyroscopes, one or more chemical sensors, one or more conductance sensors, one or more electrical resistance sensors, one or more photoelectric sensors, and/or the like.

The system 1000 can further comprise computing circuitry 1004 configured to receive signals and/or sensor data from the distributed sensor network 1002. The computing circuitry 1004 can be configured to interpret the signals and/or the sensor data to determine, e.g., biometric information or the like. In some embodiments, the computing circuitry 1004 can comprise, be configured to access, be configured to communicate with, or otherwise support the use of one or more models, programs, or the like (e.g., a predictive model, a machine learning model, an artificial intelligence program, etc.) that is/are configured to interpret sensor signals and/or sensor data received from the distributed sensor network 1002. In some embodiments, the computing circuitry 1004 or the like can be in operable communication with one or more external user devices 1006 of a user, such as a smart phone, computer, tablet, wearable device, mobile device, remote device, user device, and/or the like. In some embodiments, the distributed sensor network 1002 can communicate directly with the computing circuitry 1004. In some embodiments, the distributed sensor network 1002 can communicate with the computing circuitry 1004 via the one or more external user devices 1006.

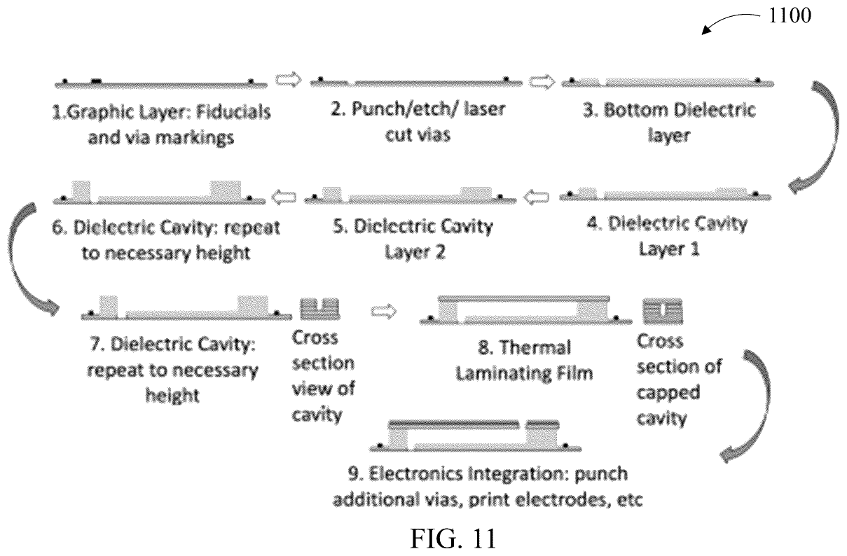

FIG. 11 illustrates a process 1100 for screen-printing. The process 1100 can comprise fabrication of flexible cavities were fabricated using a 3D screen printing method consisting of successive printing of dielectric layers. In some embodiments, one or more substrates (e.g., 7-mil-thick polyethelene terepthalate (PET)) can be provided and prepared by cleaning the surface (e.g., with 99% isopropyl alcohol) to remove environmental contaminants. A graphic layer can be screen printed thereon to create fiducials (operation 1). In some embodiments, additional markings can be added to the substrate or graphic layer for specific device fabrication (operation 1). Further substrate preparation, including the cutting of vias and screen printing of conductive traces can then be performed (operation 2).

As shown, a first dielectric ink layer can be deposited (operation 3) using, e.g., a stainless-steel mesh screen patterned with the cavity geometry, (at operation 4), cured using UV LEDs, then repeated until the desired cavity height is reached (at operations 5-7). A laminated roller press can be used to adhere a thermal film to a top of the patterned cavity geometry (at operation 8). Additional device elements can then be screen printed on top of the film (operation 9) to complete the process 1100.

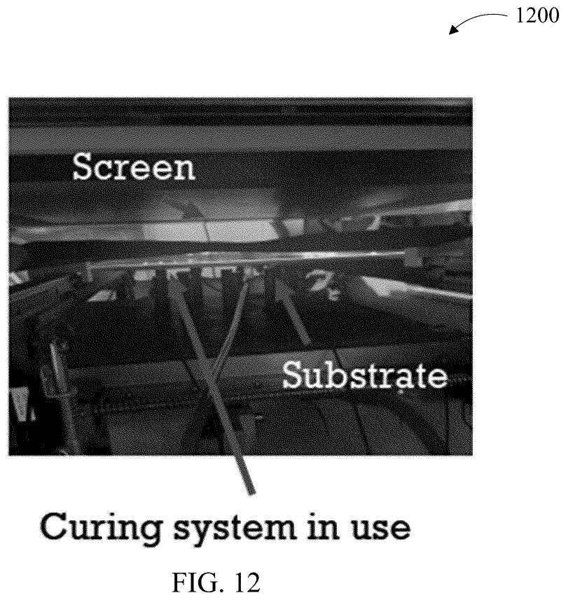

FIG. 12 is a photograph of a portion of a screen-printing system 1200 in which a screen (e.g., 104) is disposed above a substrate (e.g., 102). The screen-printing system 1200 is configured to fabricate fully screen-printed micro-cavities and micro-scale devices. The screen-printing system 1200 was found to reduce print registration error during the fabrication process. The screen-printing system 1200 can comprise one or more ultraviolet (UV) light-emitting diodes (LEDs) (not shown). The UV LEDs can be positioned between the substrate and screen after printing to cure the ink without removal from the screen printer. In some embodiments, the UV LEDs can be operably coupled (e.g., movably coupled) to or about the screen of the screen-printing system 1200. In some embodiments, the UV LEDs can be mounted on a frame of the screen-printing system 1200. In some embodiments, the UV LEDs can be mounted on one or more roller support elements (not shown) of the screen-printing system 1200. In some embodiments, the UV LEDs can be mounted on, coupled to, or otherwise supported by the screen-printing system 1200 or a component thereof such that the UV LEDs can be moved in one or more directions and/or rotated in one or more directions with respect to the screen and substrate of the screen-printing system 1200. In some embodiments, the UV LEDs can be configured to be rotated, translated, slid, extended, retracted, raised, lowered, and/or otherwise moved or repositioned with respect to the screen and substrate of the screen-printing system 1200.

For example, the UV LEDs can be configured to initially be maintained in a retracted configuration away from the substrate and the screen during a printing operation when printing ink is disposed onto the substrate or a layer of already cured printing ink previously supported on the substrate. Then, after the printing operation (whether an initial printing of ink directly onto the substrate or a subsequent printing of ink as a subsequent layer supported by the substrate), the UV LEDs can be configured to be moved into an extended configuration closer to, nearby, beneath, above, between, or otherwise in sufficient proximity to the printed ink so as to be used during an in situ curing operation.

In some embodiments, the UV LEDs can be coupled to, disposed about, or retained within a distal end of a pivot arm. In some embodiments, when the UV LEDs are moved from the extended configuration into the retracted position, the distal end of the pivot arm supporting the UV LEDs can be rotated about a pivot point such that the UV LEDs are rotated away from (e.g., out from between) the substrate and the screen. In some embodiments, when the UV LEDs are moved from the retracted configuration into the extended position, the distal end of the pivot arm supporting the UV LEDs can be rotated about the pivot point such that the UV LEDs are rotated towards (e.g., in between) the substrate and the screen.

In other embodiments, the UV LEDs can be coupled to, disposed about, or retained within one or more slides. In some embodiments, when the UV LEDs are moved from the extended configuration into the retracted position, the one or more slides supporting the UV LEDs can be slid in a first direction such that the UV LEDs are translated/moved away from (e.g., out from between) the substrate and the screen. In some embodiments, when the UV LEDs are moved from the extended configuration into the retracted position, the UV LEDs supported on the one or more slides can be slid in the first direction relative to the one or more slides such that the UV LEDs are translated/moved away from (e.g., out from between) the substrate and the screen. In some embodiments, when the UV LEDs are moved from the retracted configuration into the extended position, the one or more slides supporting the UV LEDs can be slid in a second direction such that the UV LEDs are translated/moved towards(e.g., in between) the substrate and the screen. In some embodiments, when the UV LEDs are moved from the extended configuration into the retracted position, the UV LEDs supported on the one or more slides can be slid in the second direction relative to the one or more slides such that the UV LEDs are translated/moved towards (e.g., in between) the substrate and the screen.

In other embodiments, the UV LEDs can be coupled to, disposed about, or retained within one or more ridges or rollers configured to move within one or more channels. In some embodiments, when the UV LEDs are moved from the extended configuration into the retracted position, the one or more ridges or rollers supporting the UV LEDs can be moved through the one or more channels in a first direction such that the UV LEDs are translated/moved away from (e.g., out from between) the substrate and the screen. In some embodiments, when the UV LEDs are moved from the extended configuration into the retracted position, the UV LEDs supported on the one or more ridges or rollers can be slid through the one or more channels in the first direction relative to the one or more slides such that the UV LEDs are translated/moved away from (e.g., out from between) the substrate and the screen. In some embodiments, when the UV LEDs are moved from the retracted configuration into the extended position, the one or more ridges or rollers supporting the UV LEDs can be slid through the one or more channels in a second direction such that the UV LEDs are translated/moved towards(e.g., in between) the substrate and the screen. In some embodiments, when the UV LEDs are moved from the extended configuration into the retracted position, the UV LEDs supported on the one or more ridges or rollers can be slid through the one or more channels in the second direction relative to the one or more slides such that the UV LEDs are translated/moved towards (e.g., in between) the substrate and the screen.

This in situ curing process leads to micro-scale structures (i.e., device comprising one or more micro-cavities) being formed on the substrate. Depending on the application, the micro-cavities formed on the substrate may need to be covered or capped in part or in full to form the screen-printed device. For example, the micro-cavities formed via screen printing can be capped using a rolling lamination process which uses heat and pressure to adhere a PET capping layer. Additional printed layers can be added on top of the capping layer to create more complex structures.

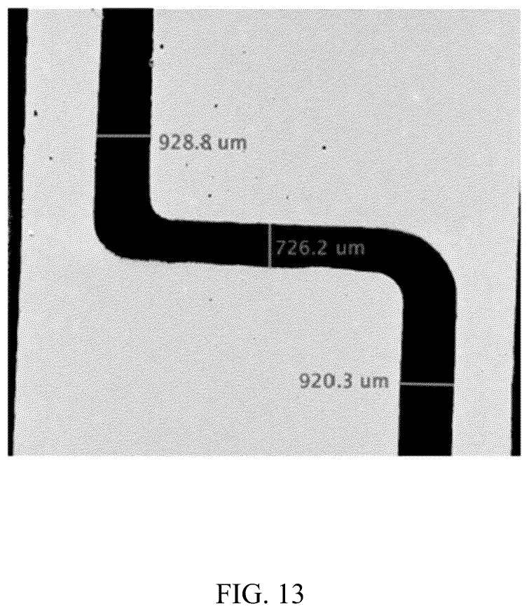

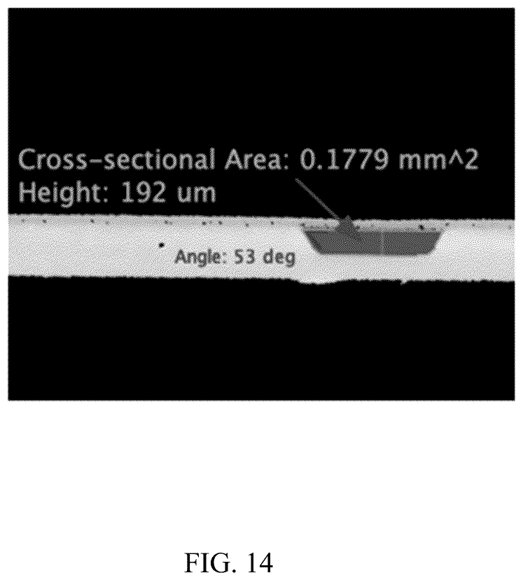

FIGS. 13 and 14 are computerized tomography (CT) images of a micro-cavity structure fabricated according to a 3D screen-printing process described herein. FIG. 13 is a mid-plane cross-sectional CT image while FIG. 14 is a perpendicular cross-sectional CT image.

The CT images, captured using a CT device (Zeiss Versa 620), were taken to analyze the 3D structure and calculate cross-sectional areas of the micro-cavity structure that was printed.

The CT image of FIG. 13 shows a variation between a channel width of a first portion of a micro-scale channel printed in a first direction than the channel width for a second portion of the micro-scale channel printed in a second direction that is different (e.g., perpendicular to) the first direction. The CT image of FIG. 13 further shows a variation between the channel width of a third portion of the micro-scale channel printed in the first direction and the channel width of the first portion or the second portion of the micro-scale channel. The first section of the micro-cavity structure illustrated in FIG. 13 had a channel width of about 928 μm. Further, the second section of the micro-cavity structure illustrated in FIG. 13 was oriented approximately perpendicular to the first section of the micro-cavity structure and the second section of the micro-cavity structure had a channel width of about 726 μm. Additionally, the third section of the micro-cavity structure illustrated in FIG. 13 was oriented approximately perpendicular to the second section of the micro-cavity structure and was oriented approximately parallel to the first section of the micro-cavity structure. Also, the first section of the micro-cavity structure illustrated in FIG. 13 had a channel width of about 920 μm.

In the particular example illustrated in FIG. 13, the first and third portions of the micro-scale channel were oriented approximately or substantially parallel with a print direction (i.e., in line with the screen-printing direction), while the second portion of the micro-scale channel was oriented approximately or substantially perpendicular to the print direction. The CT image of FIG. 13 shows that, at least in the particular embodiment being illustrated, channel width decreased from about 920 μm to about 726 μm when printing parallel vs. perpendicular to the print direction.

As noted above, FIG. 14 is a perpendicular cross-sectional CT image of the micro-cavity structure illustrated in FIG. 13. The CT imaged micro-cavity structure illustrated in FIG. 14 has a measured cross-sectional area of 0.1179 mm² and a measured cavity height of 192 μm. FIG. 14 further shows that the sidewalls formed at an angle of 53°. Without wishing to be bound by any particular theory, this may be due to ink bleed from each successive layer flowing towards the substrate before the curing of the ink.

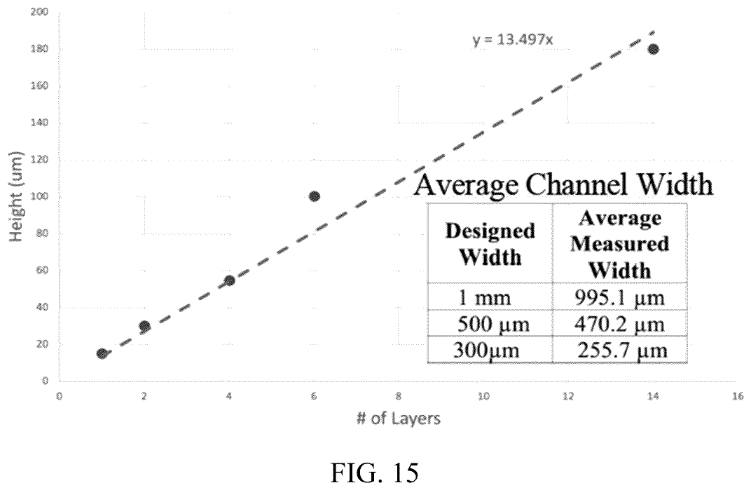

FIG. 15 is a graph showing average channel height of a micro-scale channel 3D screen as compared to the number of print layers printed. As shown, the average channel height generally correlates with (e.g., linearly) the number of print layers printed during formation of the micro-scale channel.

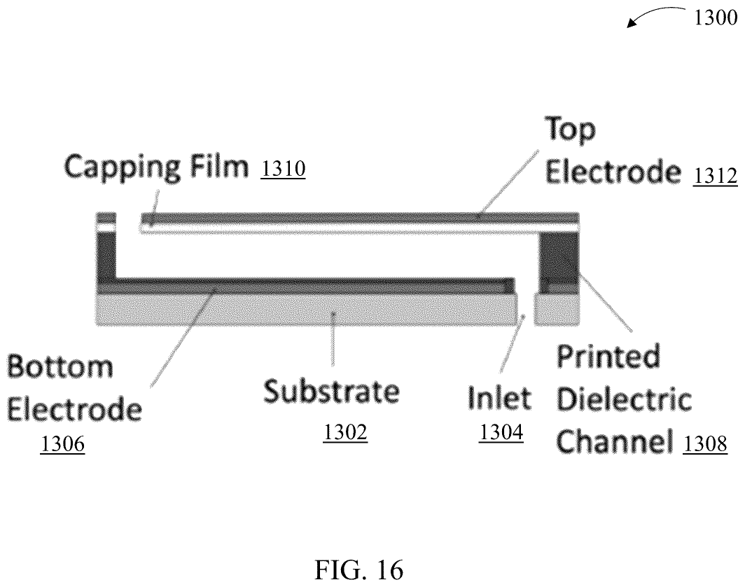

FIG. 16 illustrates a 3D screen-printed micro-cavity device 1300 comprising a substrate 1302. The substrate 1302 can comprise or define an inlet 1304 therethrough from a bottom side to a top side of the substrate 1302. The 3D screen-printed micro-cavity device 1300 further comprises a bottom electrode 1306 that is disposed or supported on a top surface of the substrate 1302. The bottom electrode 1306 can also comprise or define an aperture therethrough that aligns with the inlet 1304 in the substrate 1302.

The 3D screen-printed micro-cavity device 1300 further comprises a printed dielectric channel 1308 disposed on the bottom electrode 1306. The printed dielectric channel 1308 can comprise one or more layers formed by 3D screen printing.

The 3D screen-printed micro-cavity device 1300 further comprises capping film 1310. The capping film 1310 can be disposed over or across the printed dielectric channel 1308. The capping film 1310 can be unrolled or dispensed from another roller and received on another roller.

The 3D screen-printed micro-cavity device 1300 further comprises a top electrode 1312. The top electrode 1312 can be disposed over or across the capping film 1310 once the capping film 1310 is disposed over the printed dielectric channel 1308.

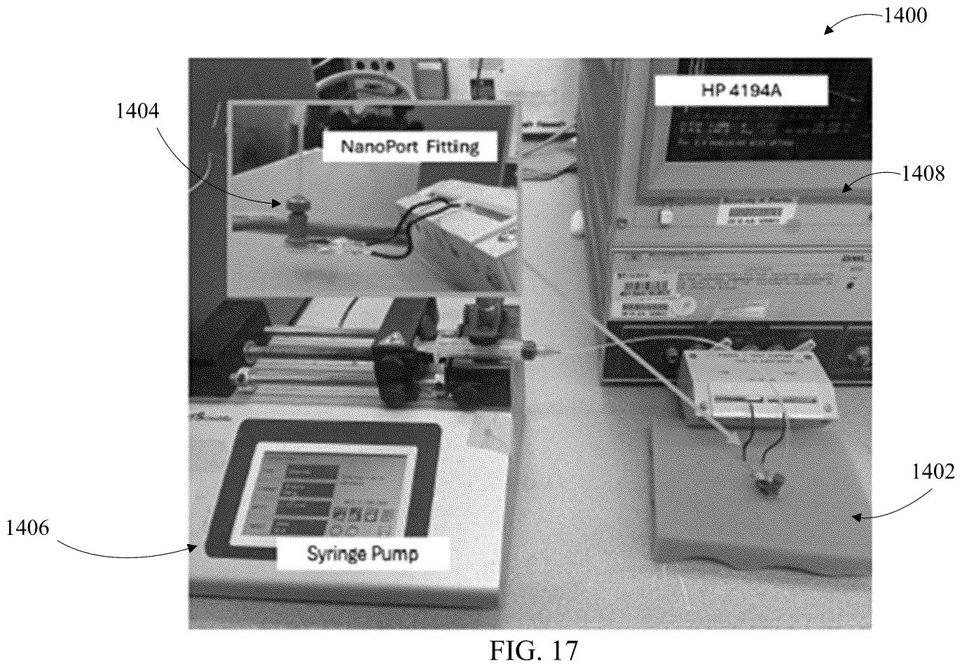

FIG. 17 illustrates a testing system 1400. The testing system 1400 can be configured for testing the performance of microfluidic structures (e.g., designed width microfluidic capacitive test structures) as a proof of concept for use in, e.g., various sensing systems and other applications. The testing system 1400 was used to analyze and characterize the geometry and the impact of different print parameters on the performance of each final microfluidic structure.

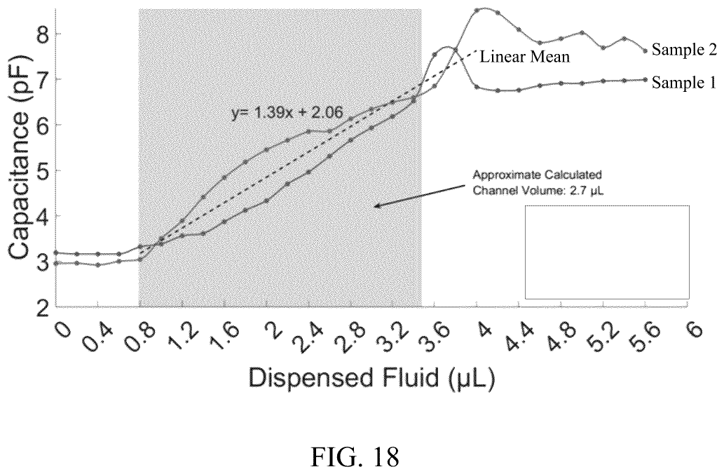

The sensor testing system 1400 can comprise a testing platform 1402 in operable communication with a NanoPort connector fitting 1404. The test system 1400 further comprises a syringe pump 1406 for precise dispensing of water through the NanoPort connector fitting 1404. The testing device 1400 can further comprise an impedance analyzer 1408 (e.g., HP 4914A) configured to measure capacitance. Testing was performed on a variety of different microfluidic structures using the testing system 1400. Select results from that testing is shown in FIG. 18.

FIG. 18 is a graph illustrating select results from testing different microfluidic structures and devices having a range of different dimensions and/or form factors (e.g., different channel widths, different channel heights, and/or channel volumes). As shown in the graph of FIG. 18, measurable capacitance changes from 3 pf to 7 pF were observed as fluid volume increased to the calculated channel volume, with an average capacitance of 1.39 pF/μL for the microfluidic structures and devices tested.

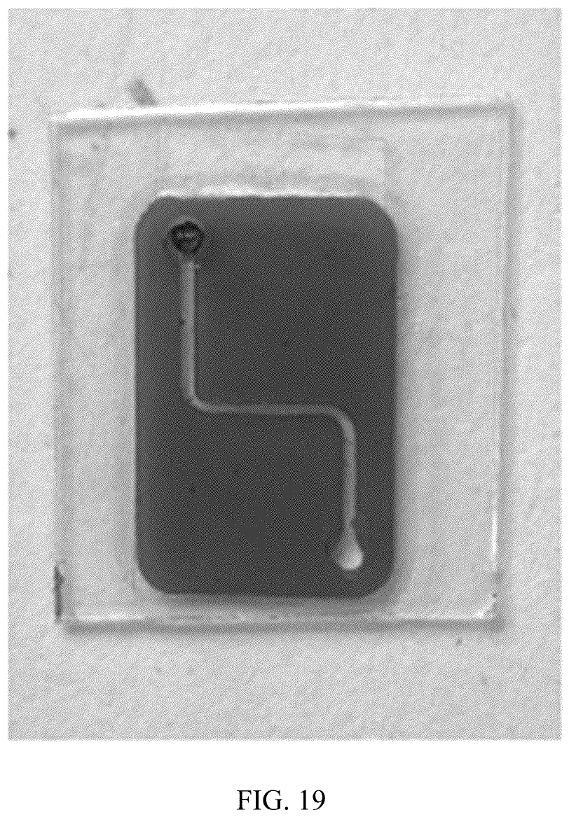

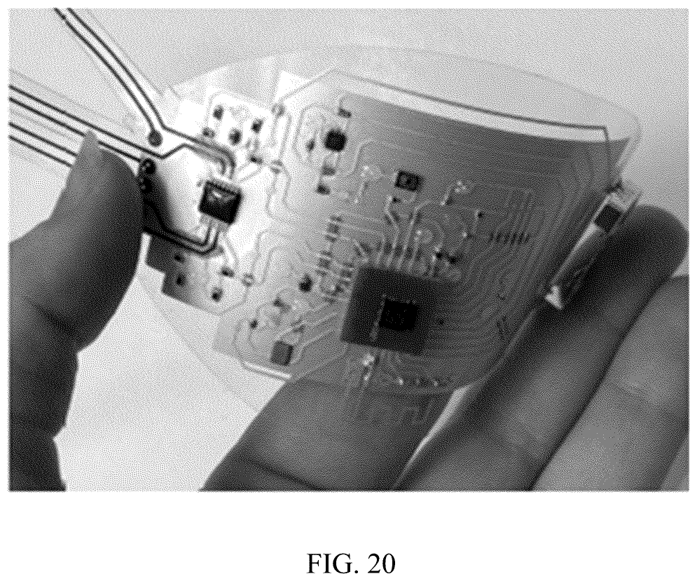

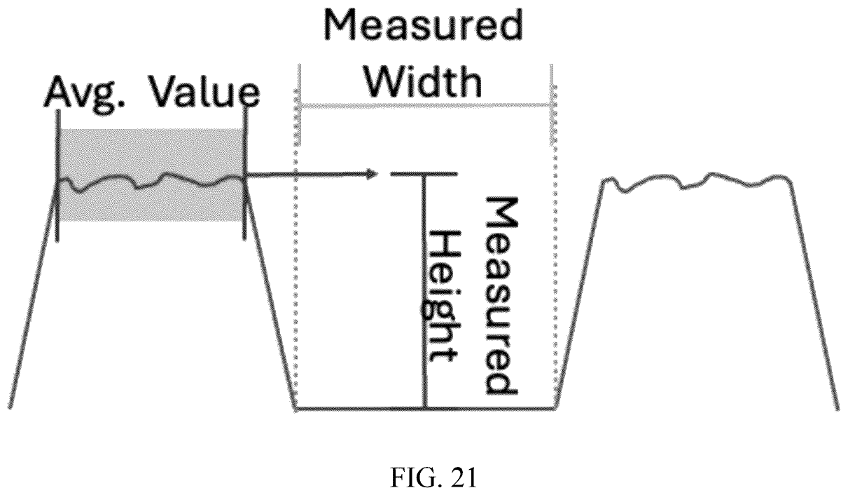

FIGS. 19 and 20 show, respectively, an example of a screen printed microfluidic channel structure and an example of a flexible sensor comprising a screen printed microfluidic channel structure. Results from the performance testing of the microfluidic channel structure of FIG. 19, for example to compare channel width to the designed geometry and height as a function of deposited layers was performed using stylus profilometry (Dektak 150, Tencor Alpha-step AS500), as shown in FIGS. 21-23.

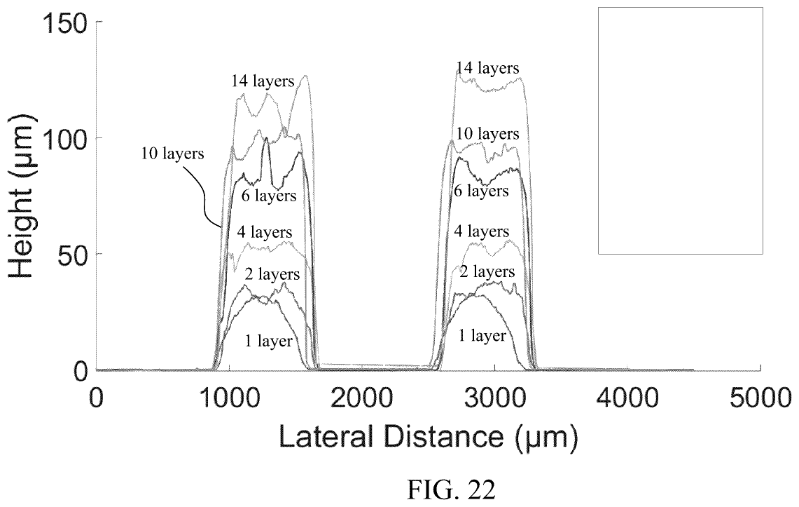

FIG. 21 is a graph that illustrates the measurement points for channel/cavity measurements. FIG. 22 shows linear growth in height with regard to the number of printed layers, indicating that the thickness of the deposited layers is not appreciably affected by the height of the structure.

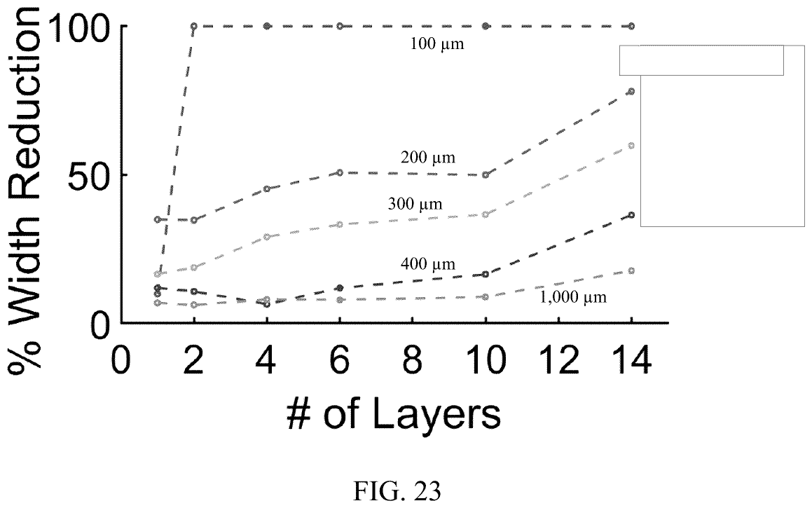

FIG. 23 is a graph that illustrates the reduction of cavity width as the number of layers printed changes for a particular ink and under similar curing conditions. The difference in the measured width of the channel compared to the designed width is due to ink bleed during the printing process, which can vary based on the specific printing parameters and ink chosen. The minimum width achieved under these conditions was about 30 μm using a microfluidic channel structure having an average width of about 100 μm and using only a single print layer. At a designed width of about 200 μm, measured widths of about 100 μm were achieved for microfluidic devices implementing, e.g., 14 printed layers.

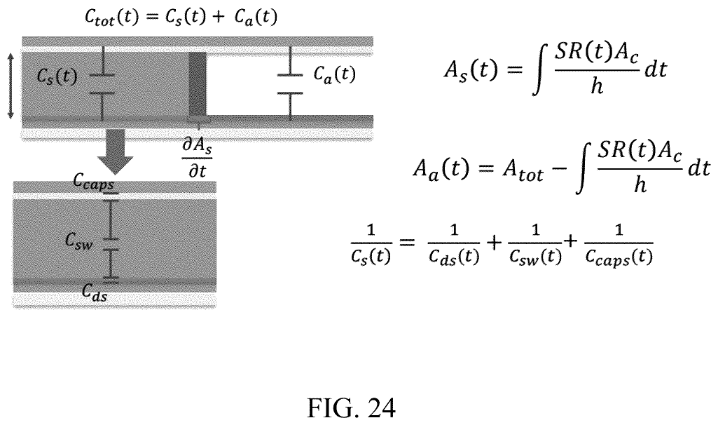

FIG. 24 illustrates a circuit model for a sample capacitive sensor fabricated using a 3D screen printing process. For example, for a capacitive sweat sensor, a sweat rate can be calculated, e.g., using the equations shown in FIG. 24, based upon a measured change in capacitance over time, as a function of the change in the sweat filled area of the sensor. Testing of the sample capacitive sensor can be performed using, e.g., the testing system 1400.

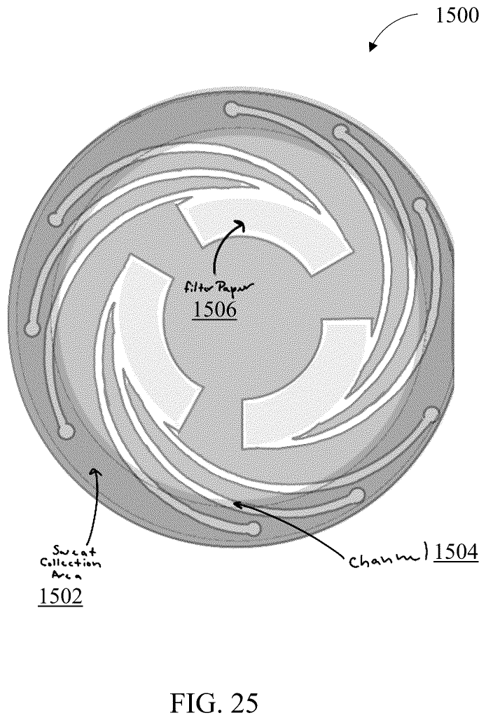

FIG. 25 illustrates an example of a microfluidic device 1500 configured to be integrated into a capacitive sensor, e.g., a sweat sensor. The microfluidic device 1500 can have any suitable form factor and/or dimensions as need for a particular application and/or for integration into a particular sensor or other such device. For example, the microfluidic device 1500 illustrated in FIG. 25 has a generally circular shape. The microfluidic device 1500 can comprise one or more sweat collection areas 1502 at one or more locations about an outer edge of the microfluidic device 1500. The microfluidic device 1500 can further comprise one or more micro-scale channels 1504. The micro-scale channel(s) 1504 can be in fluidic communication with the one or more sweat collection areas 1502. The microfluidic device 1500 can further comprise one or more filter paper portions 1506 disposed at or near a center of the microfluidic device 1500. The one or more filter paper portions 1506 can also be in fluidic communication with the micro-scale channels 1504 such that sweat collected at the sweat collection areas 1502 can be communicated through the micro-scale channels 1504 and to the filter paper portions 1506.

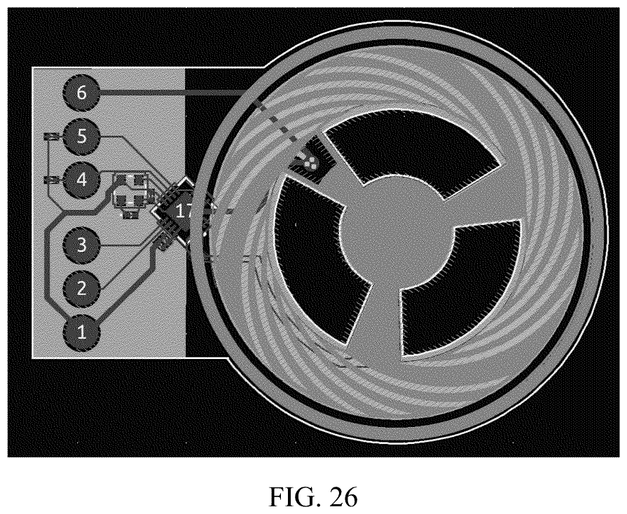

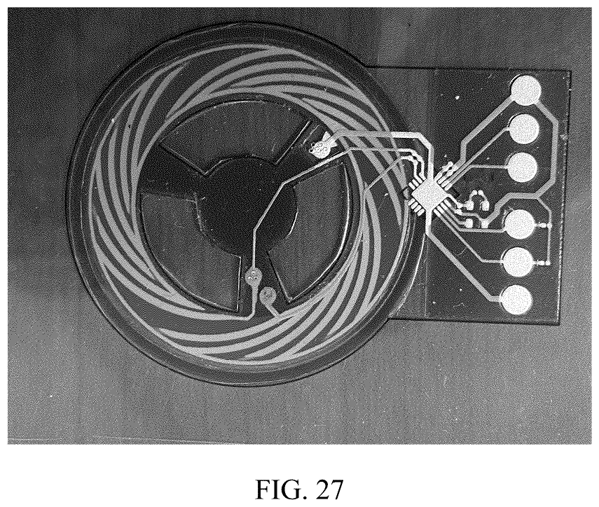

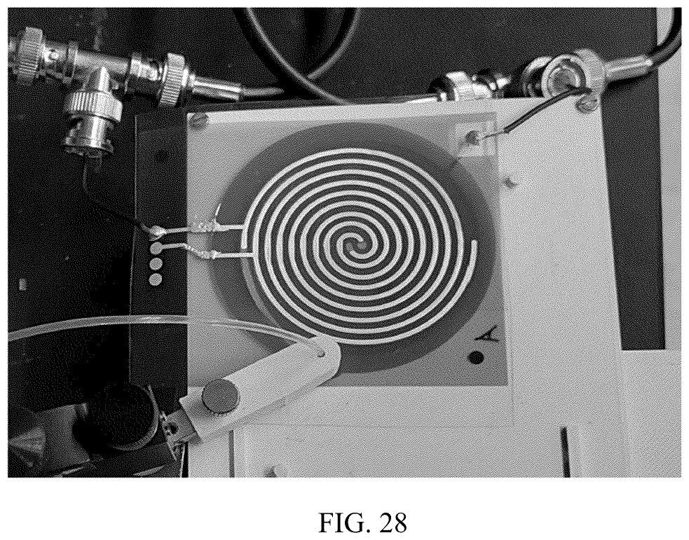

FIGS. 26-28 are photographs of various sensor devices incorporating a microfluidic device, such as the microfluidic device 1500 illustrated in FIG. 25. In these sensor devices, the microfluidic device (e.g., 1500) forms an inlet to the micro-scale channel(s) (e.g., 1504) that receives a material (e.g., sweat) being collected, communicates that material therethrough, and communicates the material to one or more sample testing portions (e.g., filter paper portions 1506) such that the material can be collected and tested.

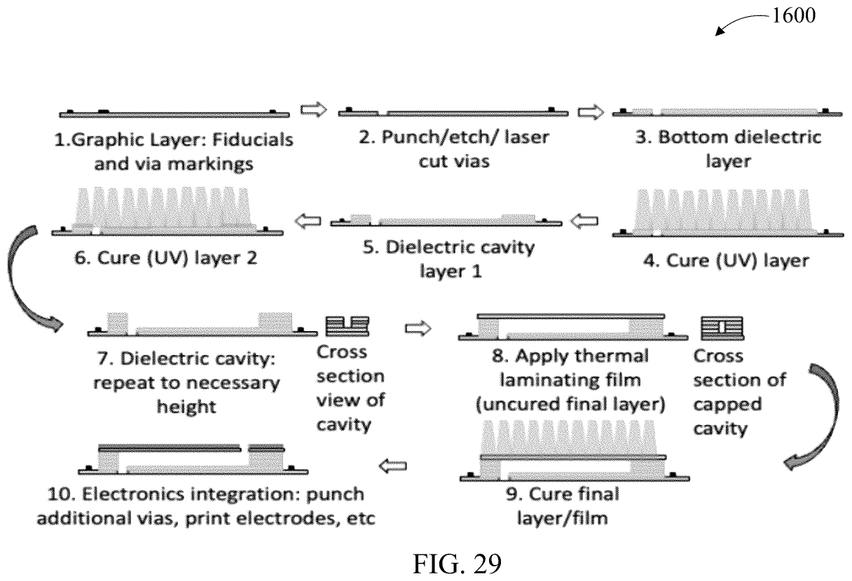

Referring now to FIG. 29, an example of a 3D screen-printing process 1600 is illustrated which includes steps 1-9. In step 1 of the 3D screen-printing process 1600, graphic layer fiducials and via markings are screen-printed onto a substrate. The graphic layer fiducials and via markings are useful during subsequent screen-printing steps to properly align the printing screens and proper alignment thereafter of the structures printed on the substrate using the printing screens.

In step 2 of the 3D screen-printing process 1600, if needed, vias are punched, etched, or lasered into the substrate.

In step 3 of the 3D screen-printing process 1600, a bottom dielectric layer is screen-printed on top of the substrate using a printing screen aligned according to the graphic layer fiducials and vias added to or subtractively formed on the substrate.

In step 4 of the 3D screen-printing process 1600, a first portion of a dielectric cavity is formed via screen-printing of a first portion of one or more structures around the dielectric cavity that defines the first portion of the dielectric cavity.

In step 5 of the 3D screen-printing process 1600, a second portion of the dielectric cavity is formed via screen-printing of a second portion of the one or more structures around the dielectric cavity that define the second portion of the dielectric cavity. The second portion of the dielectric cavity can be partially or completely formed on a top surface of the first portion of the one or more structures that define the dielectric cavity.

In step 6 of the 3D screen-printing process 1600, a third portion of the dielectric cavity is formed via screen-printing of a third portion of the one or more structures around the dielectric cavity that defines the third portion of the dielectric cavity. The third portion of the dielectric cavity can be partially or completely formed on a top surface of the second portion of the one or more structures that define the dielectric cavity.

In step 7 of the 3D screen-printing process 1600, a fourth portion and, optionally, subsequent portions of the dielectric cavity is/are formed via screen-printing of a fourth, and optionally subsequent portions, of the one or more structures around the dielectric cavity that define the second portion of the dielectric cavity. The fourth portion of one or more structures that define the dielectric cavity can be partially or completely formed on a top surface of the third portion of the one or more structures that define the dielectric cavity. Subsequent portions of the one or more structures that define the dielectric cavity can be iteratively screen-printed onto the top surface of the fourth portion of the one or more structures that define the dielectric cavity, and so on and so forth until a desired dimensions (e.g., height) and/or form factor of the dielectric cavity is achieved.

In step 8 of the 3D screen-printing process 1600, a thermal laminating film is adhered to the one or more structures that stand proud of the substrate and which define the dielectric cavity, thereby capping the dielectric cavity between the one or more structures, the thermal laminating film, and a bottom surface (e.g., an initially screen-printed layer or the substrate), to form a microscale dielectric cavity structure for use in FHEs.

In step 9 of the 3D screen-printing process 1600, the microscale dielectric cavity structure is integrated into the FHE. In some embodiments, to do this, additional vias are punched, and electrodes are printed on the dielectric cavity structure, among other processes and actions.

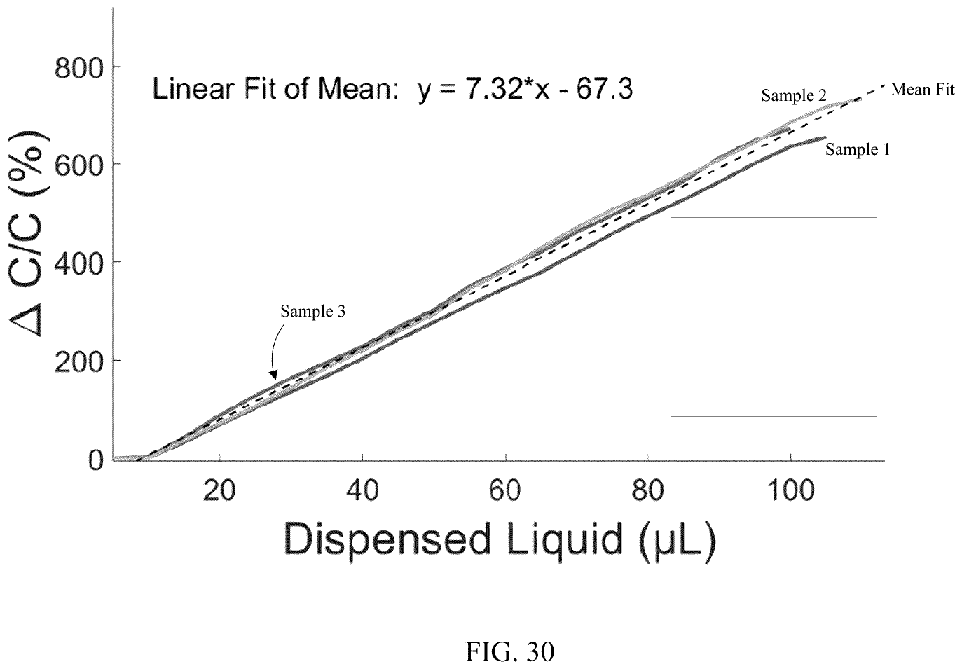

Referring now to FIG. 30, a graph is presented which illustrates measured height of example fabricated cavity structures as a function of the number of deposited layers, which demonstrates linear growth as the number of printed layers increases. The example fabricated cavity structures were characterized to analyze the structure's geometry and the impact of print parameters on the final structure. Evaluation of the measured cavity size in relation to the designed geometry and height as a function of deposited layers was performed using stylus profilometry. It was determined that the thickness of the deposited layer is not affected by the height of the structure. The calculated thickness per layer was about 13.5 μm.

Three samples of each width were printed with 14 layers to achieve an approximate height of 190 μm. The difference in the measured width of the channel compared to the designed width is due to ink bleed during the printing process and can vary based on the specific printing parameters and ink chosen. The measured samples were printed using the same print parameters, and measurements were all taken from samples printed parallel to squeegee direction.

FIG. 30 is a graph that illustrates measured percent change in capacitance of example sensors as a function of liquid volume for three selected samples. A mean sensitivity of 7.32%/μL was calculated with a standard deviation of 0.30.

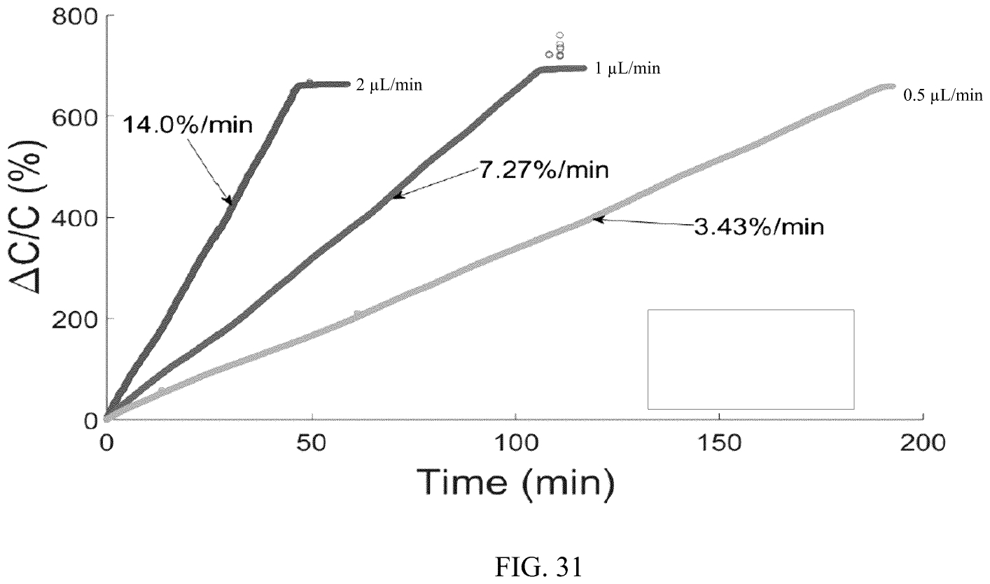

FIG. 31 is a graph or measured sensor response (normalized capacitance change) versus time at dispense rates of 0.5 uL/min, 1 uL/min, and 2 uL/min. Flow rate was determined by calculating the slope of each response. The calculated flow rates were 0.494 μL/min, 1.05 μL/min, and 2.01 μL/min, respectively, with a measurement uncertainty of +/−5%.

Some or all of the 3D screen-printing approaches described herein can be initiated by a computing device, caused to be performed by a computing device, or carried out directly by a computing device. For example, various elements and steps, such as the communication of cross-linkable printing ink between the printing ink reservoir 106 and the nozzle 110 of the 3D screen-printing system 100 can be performed by one or more pumps, one or more valves, one or more sensors, and/or the like, which may be controlled by a computing device, such as according to a program or application stored or hosted on the computing device. As another example, the selection of a particular printing screen 102 from among a plurality of printing screens (e.g., 105) can be controlled by a computing device. As another example, the movement of the printing screen 104 onto or above the substrate 102 can be controlled by a computing device. As another example, the reciprocation of the squeegee 116 across the printing screen 104 can be controlled by a computing device. Likewise, the extension and/or retraction and/or positioning of the retractable light source 108, as well as the duration and intensity of UV light emission therefrom can be controlled by a computing device. The initiation and speed of advancement of the dispensing roll 112 and the collecting roll 116 can be controlled by a computing device. Many other elements or aspects of the systems, methods, devices, and processes described herein can be carried out by a computing device. Examples of such computing devices are described as follows.

### Computer Program Products, Methods, and Computing Entities

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language, such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established, or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In some embodiments, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In some embodiments, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As will be appreciated by a person skilled in the art, various embodiments of the present disclosure may also be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some embodiments, retrieval, loading, and/or execution may be performed in parallel such that multiple instructions are retrieved, loaded, and/or executed together. Thus, such embodiments can produce specifically-configured machines performing the steps or operations specified in the block diagrams and flowchart illustrations. Accordingly, the block diagrams and flowchart illustrations support various combinations of embodiments for performing the specified instructions, operations, or steps.

### Example Computing Entity

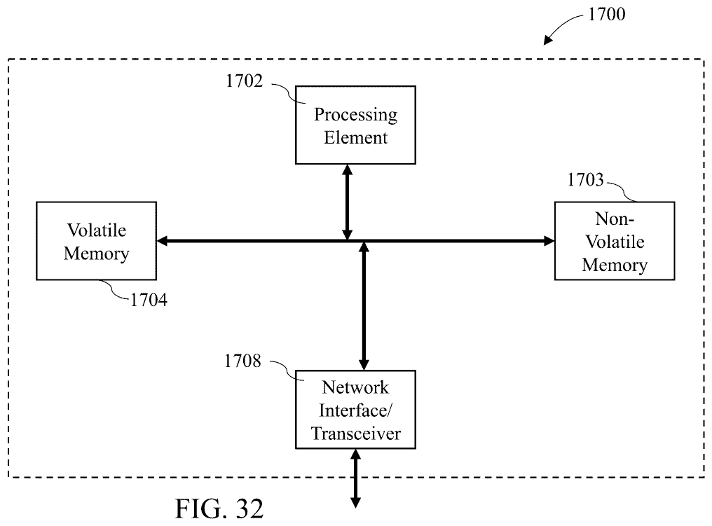

FIG. 32 provides a schematic of the computing device 1700 according to one embodiment of the present disclosure. In general, the terms computing device, computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As shown in FIG. 32, the computing device 1700 may include or be in communication with one or more processing elements 1702 (also referred to as processors, processing circuitry, and/or similar terms used herein interchangeably) that communicate with other elements within the computing device 1700 via a bus, for example. As will be understood, the processing element 1702 may be embodied in a number of different ways. For example, the processing element 1702 may be embodied as one or more complex programmable logic devices (CPLDs), microprocessors, multi-core processors, coprocessing entities, application-specific instruction-set processors (ASIPs), microcontrollers, and/or controllers. Further, the processing element 1702 may be embodied as one or more other processing devices or circuitry. The term circuitry may refer to an entirely hardware embodiment or a combination of hardware and computer program products. Thus, the processing element 1702 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processing element 1702 may be configured for a particular use or configured to execute instructions stored in volatile or non-volatile media or otherwise accessible to the processing element 1702. As such, whether configured by hardware or computer program products, or by a combination thereof, the processing element 1702 may be capable of performing steps or operations according to embodiments of the present disclosure when configured accordingly.

In some embodiments, the computing device 1700 may further include or be in communication with non-volatile media (also referred to as non-volatile storage, memory, memory storage, memory circuitry, and/or similar terms used herein interchangeably). In one embodiment, the non-volatile storage or memory may include the one or more non-volatile memories 1703, including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In some embodiments, the computing device 1700 may further include or be in communication with volatile media (also referred to as volatile storage, memory, memory storage, memory circuitry, and/or similar terms used herein interchangeably). In one embodiment, the volatile storage or memory may also include one or more volatile memories 1704, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 1702. Thus, the databases, database instances, database management systems, data, applications, programs, program modules, scripts, source code, object code, byte code, compiled code, interpreted code, machine code, executable instructions, and/or the like may be used to control certain aspects of the operation of the computing device 1700 with the assistance of the processing element 1702 and operating system.

In some embodiments, the computing device 1700 may also include one or more network interfaces, such as a transceiver 1708 for communicating with various computing entities, such as by communicating data, content, information, and/or similar terms used herein interchangeably that can be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing device 1700 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing device 1700 may include or be in communication with one or more input elements, such as a keyboard input, a mouse input, a touch screen/display input, motion input, movement input, audio input, pointing device input, joystick input, keypad input, and/or the like. The computing device 1700 may also include or be in communication with one or more output elements (not shown), such as audio output, video output, screen/display output, motion output, movement output, and/or the like.

### Example External Computing Entity

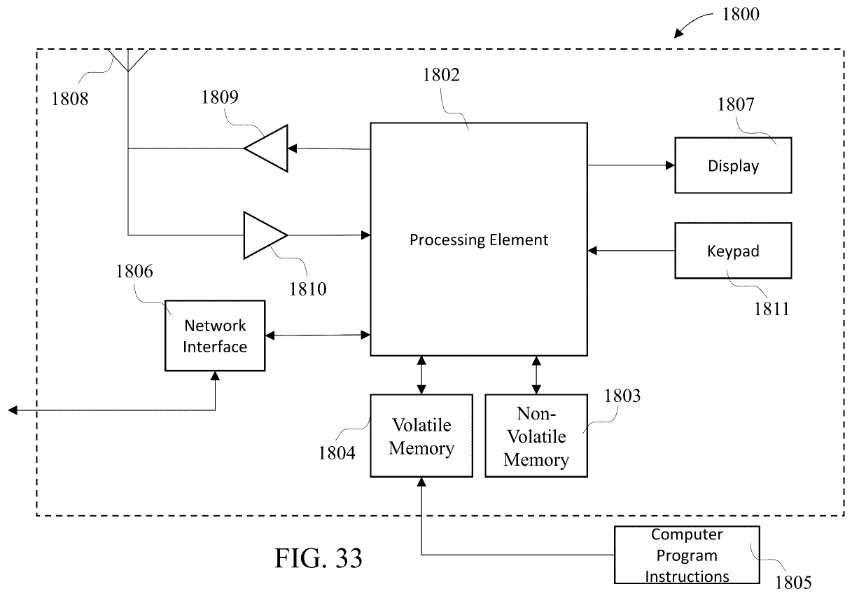

FIG. 33 provides an illustrative schematic representative of an external computing device 1800 that can be used in conjunction with embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. The external computing device 1800 can be operated by various parties. As shown in FIG. 33, the external computing device 1800 can include an antenna 1807, a transmitter 1806a (e.g., radio), a receiver 1806b (e.g., radio), and a processing element 1802 (e.g., CPLDs, microprocessors, multi-core processors, coprocessing entities, ASIPs, microcontrollers, and/or controllers) that provides signals to and receives signals from the transmitter 1806a and receiver 1806b, correspondingly.

The signals provided to and received from the transmitter 1806a and the receiver 1806b, correspondingly, may include signaling information/data in accordance with air interface standards of applicable wireless systems. In this regard, the external computing device 1800 may be capable of operating with one or more air interface standards, communication protocols, modulation types, and access types. More particularly, the external computing device 1800 may operate in accordance with any of a number of wireless communication standards and protocols, such as those described above with regard to the computing device 1700. In a particular embodiment, the external computing device 1800 may operate in accordance with multiple wireless communication standards and protocols, such as UMTS, CDMA2000, 1xRTT, WCDMA, GSM, EDGE,TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the external computing device 1800 may operate in accordance with multiple wired communication standards and protocols, such as those described above with regard to the computing device 1700 via a network interface 1808.

Via these communication standards and protocols, the external computing device 1800 can communicate with various other entities using concepts, such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The external computing device 1800 can also download changes, add-ons, and updates, for instance, to its firmware, software (e.g., including executable instructions, applications, program modules), and operating system.

According to one embodiment, the external computing device 1800 may include location determining aspects, devices, modules, functionalities, and/or similar words used herein interchangeably. For example, the external computing device 1800 may include outdoor positioning aspects, such as a location module adapted to acquire, for example, latitude, longitude, altitude, geocode, course, direction, heading, speed, universal time (UTC), date, and/or various other information/data. In one embodiment, the location module can acquire data, sometimes known as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data can be collected using a variety of coordinate systems, such as the Decimal Degrees (DD); Degrees, Minutes, Seconds (DMS); Universal Transverse Mercator (UTM); Universal Polar Stereographic (UPS) coordinate systems; and/or the like. Alternatively, the location information/data can be determined by triangulating a position of the external computing device 1800 in connection with a variety of other systems, including cellular towers, Wi-Fi access points, and/or the like. Similarly, the external computing device 1800 may include indoor positioning aspects, such as a location module adapted to acquire, for example, latitude, longitude, altitude, geocode, course, direction, heading, speed, time, date, and/or various other information/data. Some of the indoor systems may use various position or location technologies, including RFID tags, indoor beacons or transmitters, Wi-Fi access points, cellular towers, nearby computing devices (e.g., smartphones, laptops), and/or the like. For instance, such technologies may include the iBeacons, Gimbal proximity beacons, Bluetooth Low Energy (BLE) transmitters, NFC transmitters, and/or the like. These indoor positioning aspects can be used in a variety of settings to determine the location of someone or something to within inches or centimeters.

The external computing device 1800 may also comprise a user interface (that can include a display 1805 coupled to the processing element 1802) and/or a user input interface (coupled to the processing element 1802). For example, the user interface may be a user application, browser, user interface, and/or similar words used herein interchangeably executing on and/or accessible via the external computing device 1800 to interact with and/or cause display of information/data from the computing device 1700, as described herein. The user input interface can comprise any of a number of devices or interfaces allowing the external computing device 1800 to receive data, such as a keypad 1809 (hard or soft), a touch display, voice/speech or motion interfaces, or other input device. In embodiments in which the external computing device 1800 includes a keypad 1809, the keypad 1809 can include (or cause display of) the conventional numeric (0-9) and related keys (#, *, etc.), and other keys used for operating the external computing device 1800 and may include a full set of alphabetic keys or set of keys that may be activated to provide a full set of alphanumeric keys. In addition to providing input, the user input interface can be used, for example, to activate or deactivate certain functions, such as screen savers and/or sleep modes.

The external computing device 1800 can also include volatile storage or memory 1803a and/or non-volatile storage or memory 1803b, which can be embedded and/or may be removable. For example, the non-volatile memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile storage or memory (1803a, 1803b) can store databases, database instances, database management systems, data, applications, programs, program modules, scripts, source code, object code, byte code, compiled code, interpreted code, machine code, executable instructions, and/or the like to implement the functions of the external computing device 1800. As indicated, this may include a user application that is resident on the entity or accessible through a browser or other user interface for communicating with the computing device 1700 and/or various other computing entities.

In another embodiment, the external computing device 1800 may include one or more components or functionalities that are the same or similar to those of the computing device 1700, as described in greater detail above. As will be recognized, these architectures and descriptions are provided for exemplary or illustrative purposes only and are not meant to limit the scope of this disclosure to one, some, or all of the various embodiments described herein.

In some embodiments, a printing apparatus/device such as described herein can comprise and/or be in communication with the computing device 1700, the computing device 1700 being suitable to carry out movement of the various components of the printing apparatus/device, flow rates or deposition/dispersal volumes, or the like. In some embodiments, the printing apparatus/device or a component thereof, e.g., the computing device 1700, can be configured to be in communication with the external computing device 1800, which can be configured to provide instructions for printing, a design file for a printed article, printing nozzle and/or non-solvent vapor dispersion apparatus path instructions, or the like to the computing device 1700, which is configured to carry out printing.

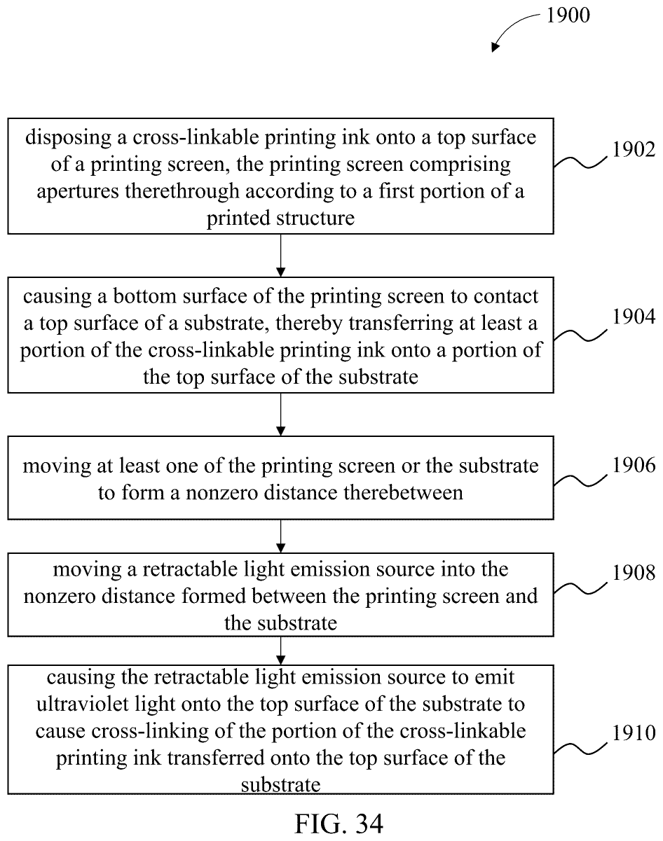

FIGS. 34-40 illustrate various 3D screen-printing methods, such as described elsewhere herein. The methods described herein can be carried out by means, such as the computing device 1700 and/or the external computing device 1800.

Referring now to FIG. 34, a method 1900 is illustrated that comprises disposing a cross-linkable printing ink onto a top surface of a printing screen, the printing screen comprising apertures therethrough according to a first portion of a printed structure, at 1902. The method 1900 can further include causing a bottom surface of the printing screen to contact a top surface of a substrate, thereby transferring at least a portion of the cross-linkable printing ink onto a portion of the top surface of the substrate, at 1904. The method 1900 can further include moving at least one of the printing screen or the substrate to form a nonzero distance therebetween, at 1906. The method 1900 can further include moving a retractable light emission source into the nonzero distance formed between the printing screen and the substrate, at 1908. The method 1900 can further include causing the retractable light emission source to emit ultraviolet light onto the top surface of the substrate to cause cross-linking of the portion of the cross-linkable printing ink transferred onto the top surface of the substrate, at 1910.

Some or all elements/steps of the method 1900 can be carried out by a device/apparatus, such as a 3D printing device. Some or all elements/steps of the method 1900 can be carried out programmatically, such as by using a computing device (e.g., 1700 and/or 1800), which can be separate from or a part of a device/apparatus for 3D printing.

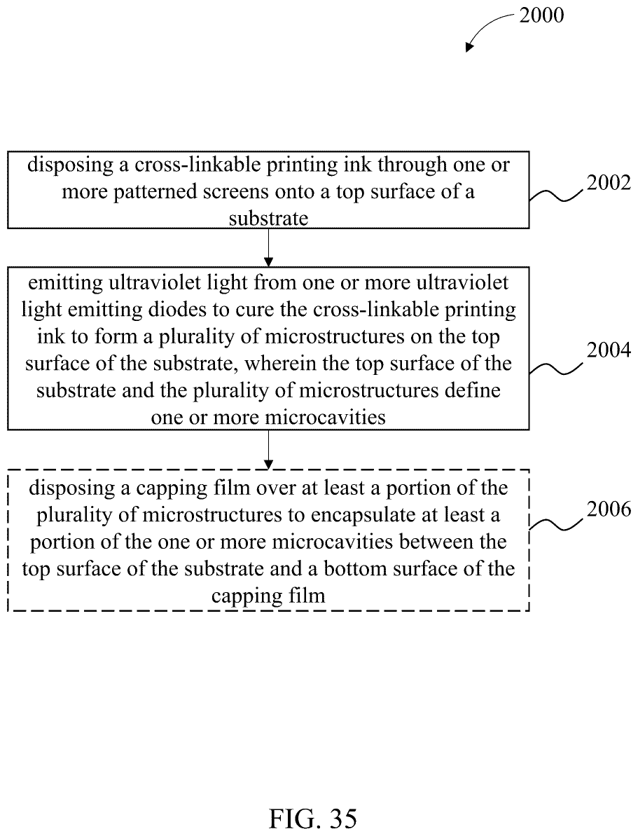

Referring now to FIG. 35, a method 2000 is illustrated that comprises disposing a cross-linkable printing ink through one or more patterned screens onto a top surface of a substrate, at 2002. The method 2000 can further include emitting ultraviolet light from one or more ultraviolet light emitting diodes to cure the cross-linkable printing ink to form a plurality of microstructures on the top surface of the substrate, wherein the top surface of the substrate and the plurality of microstructures define one or more microcavities, at 2004. The method 2000 can, optionally, further include disposing a capping film over at least a portion of the plurality of microstructures to encapsulate at least a portion of the one or more microcavities between the top surface of the substrate and a bottom surface of the capping film, at 2006.

Some or all elements/steps of the method 2000 can be carried out by a device/apparatus, such as a 3D printing device. Some or all elements/steps of the method 2000 can be carried out programmatically, such as by using a computing device (e.g., 1700 and/or 1800), which can be separate from or a part of a device/apparatus for 3D printing.

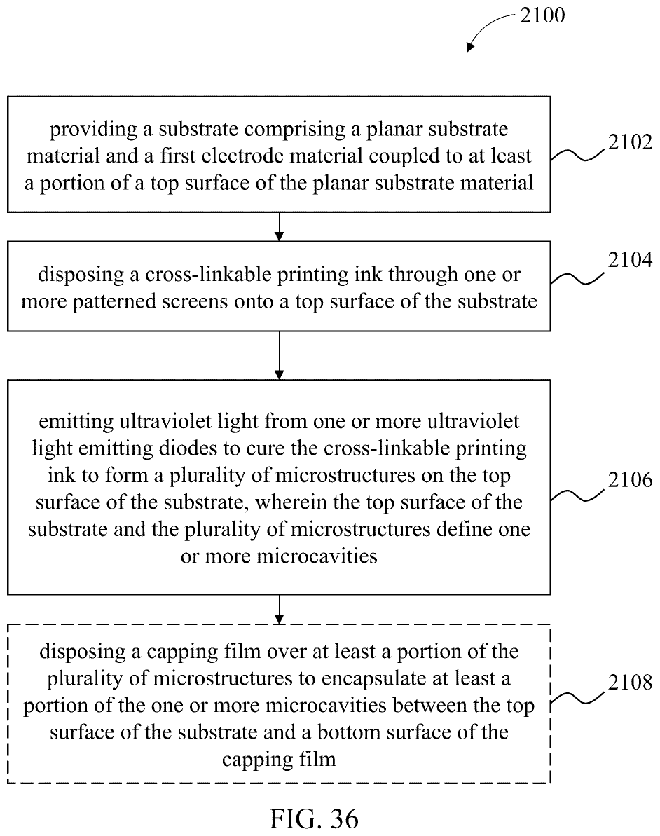

Referring now to FIG. 36, a method 2100 is illustrated that comprises providing a substrate comprising a planar substrate material and a first electrode material coupled to at least a portion of a top surface of the planar substrate material, at 2102. The method 2100 can further include disposing a resin ink through one or more patterned screens onto a top surface of the substrate, at 2104. The method 2100 can further include emitting ultraviolet light from one or more ultraviolet light emitting diodes to cure the resin ink to form a plurality of microstructures on the top surface of the substrate, wherein the top surface of the substrate and the plurality of microstructures define one or more microcavities, at 2106. The method 2100 can, optionally, further include disposing a capping film over at least a portion of the plurality of microstructures to encapsulate at least a portion of the one or more microcavities between the top surface of the substrate and a bottom surface of the capping film, at 2108.

Some or all elements/steps of the method 2100 can be carried out by a device/apparatus, such as a 3D printing device. Some or all elements/steps of the method 2100 can be carried out programmatically, such as by using a computing device (e.g., 1700 and/or 1800), which can be separate from or a part of a device/apparatus for 3D printing.

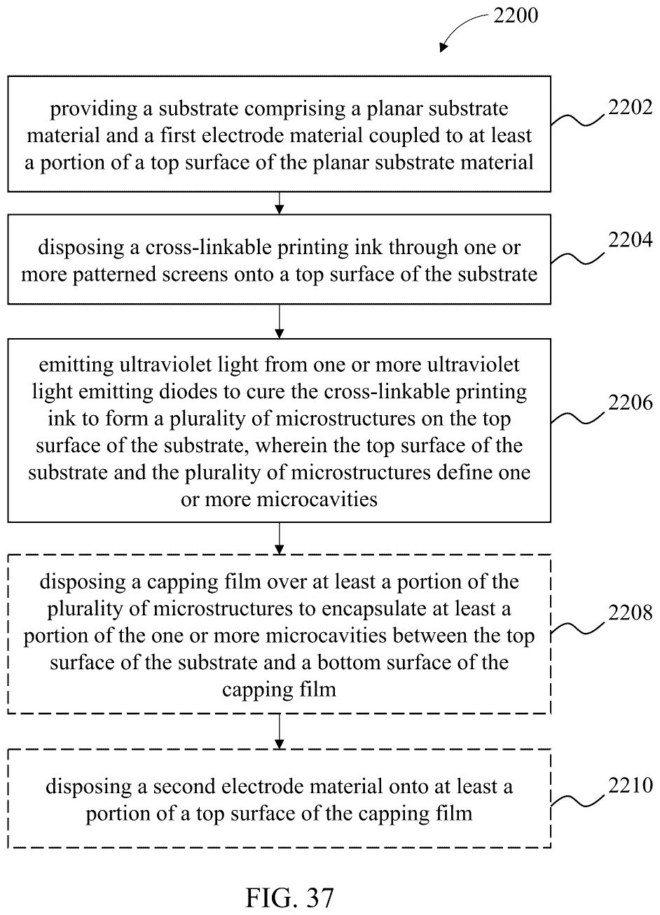

Referring now to FIG. 37, a method 2200 is illustrated that comprises providing a substrate comprising a planar substrate material and a first electrode material coupled to at least a portion of a top surface of the planar substrate material, at 2202. The method 2200 can further include disposing a cross-linkable printing ink through one or more patterned screens onto a top surface of the substrate, at 2204. The method 2200 can further include emitting ultraviolet light from one or more ultraviolet light emitting diodes to cure the cross-linkable printing ink to form a plurality of microstructures on the top surface of the substrate, wherein the top surface of the substrate and the plurality of microstructures define one or more microcavities, at 2206. The method 2200 can, optionally, further include disposing a capping film over at least a portion of the plurality of microstructures to encapsulate at least a portion of the one or more microcavities between the top surface of the substrate and a bottom surface of the capping film, at 2208. The method 2200 can, optionally, further include disposing a second electrode material onto at least a portion of a top surface of the capping film, at 2210.

Some or all elements/steps of the method 2200 can be carried out by a device/apparatus, such as a 3D printing device. Some or all elements/steps of the method 2200 can be carried out programmatically, such as by using a computing device (e.g., 1700 and/or 1800), which can be separate from or a part of a device/apparatus for 3D printing.

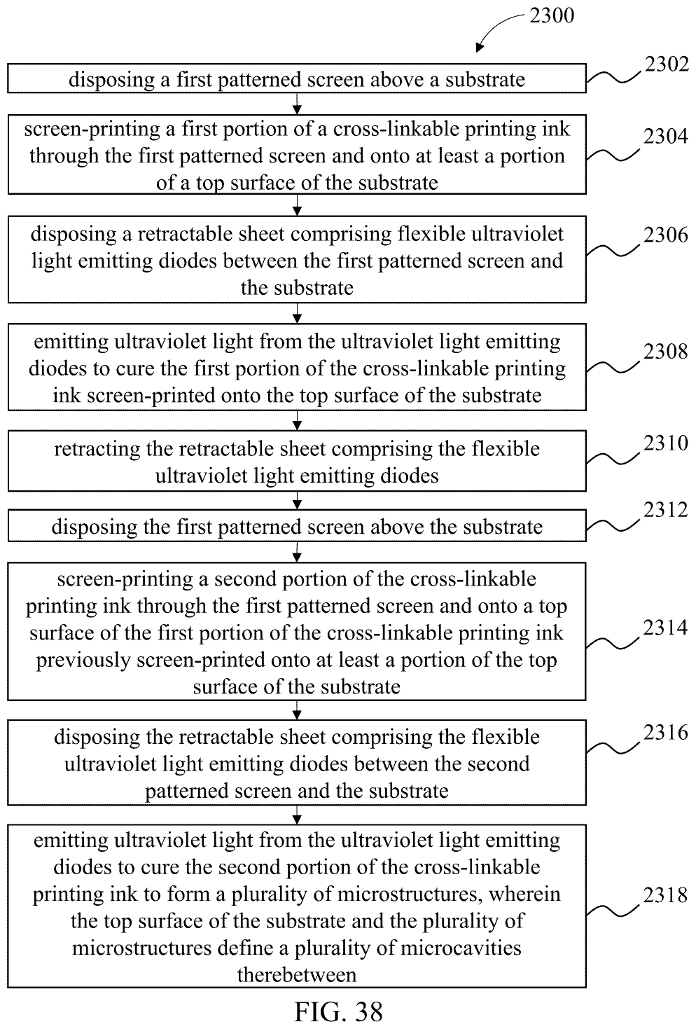

Referring now to FIG. 38, a method 2300 is illustrated that comprises disposing a first patterned screen above a substrate, at 2302. The method 2300 can further include screen-printing a first portion of a cross-linkable printing ink through the first patterned screen and onto at least a portion of a top surface of the substrate, at 2304. The method 2300 can further include disposing a retractable sheet comprising flexible ultraviolet light emitting diodes between the first patterned screen and the substrate, at 2306. The method 2300 can further include emitting ultraviolet light from the ultraviolet light emitting diodes to cure the first portion of the cross-linkable printing ink screen-printed onto the top surface of the substrate, at 2308. The method 2300 can further include retracting the retractable sheet comprising the flexible ultraviolet light emitting diodes, at 2310. The method 2300 can further include disposing the first patterned screen above the substrate, at 2312. The method 2300 can further include screen-printing a second portion of the cross-linkable printing ink through the first patterned screen and onto a top surface of the first portion of the cross-linkable printing ink previously screen-printed onto at least a portion of the top surface of the substrate, at 2314. The method 2300 can further include disposing the retractable sheet comprising the flexible ultraviolet light emitting diodes between the second patterned screen and the substrate, at 2316. The method 2300 can further include emitting ultraviolet light from the ultraviolet light emitting diodes to cure the second portion of the cross-linkable printing ink to form a plurality of microstructures, wherein the top surface of the substrate and the plurality of j

Some or all elements/steps of the method 2300 can be carried out by a device/apparatus, such as a 3D printing device. Some or all elements/steps of the method 2300 can be carried out programmatically, such as by using a computing device (e.g., 1700 and/or 1800), which can be separate from or a part of a device/apparatus for 3D printing.

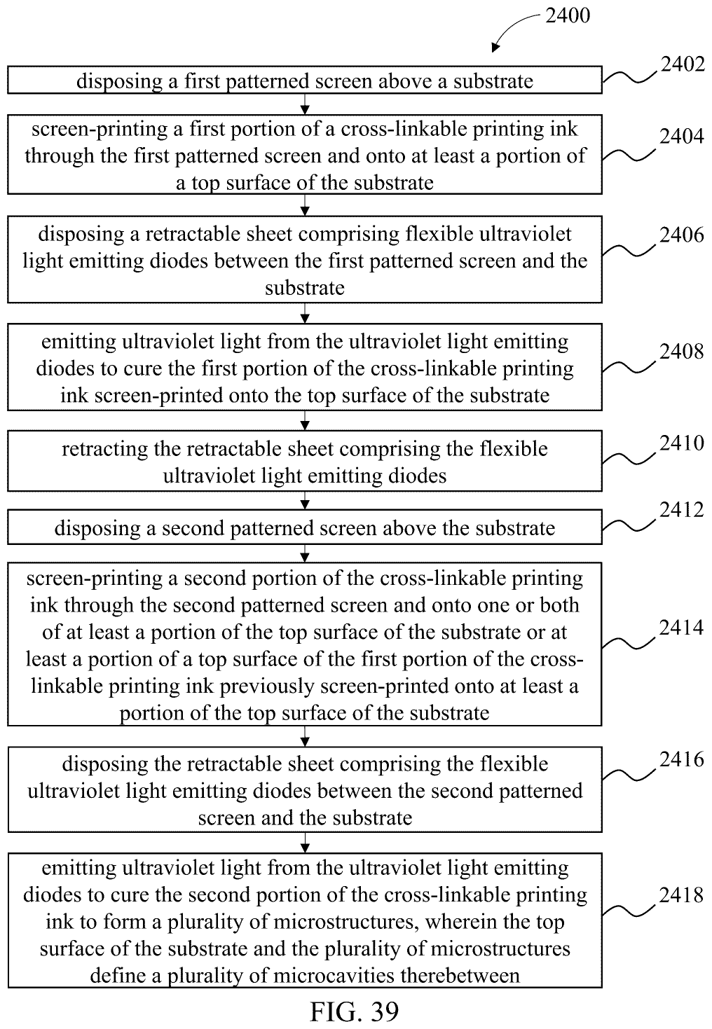

Referring now to FIG. 39, a method 2400 is illustrated that comprises disposing a first patterned screen above a substrate, at 2402. The method 2400 can further include screen-printing a first portion of a cross-linkable printing ink through the first patterned screen and onto at least a portion of a top surface of the substrate, at 2404. The method 2400 can further include disposing a retractable sheet comprising flexible ultraviolet light emitting diodes between the first patterned screen and the substrate, at 2406. The method 2400 can further include emitting ultraviolet light from the ultraviolet light emitting diodes to cure the first portion of the cross-linkable printing ink screen-printed onto the top surface of the substrate, at 2408. The method 2400 can further include retracting the retractable sheet comprising the flexible ultraviolet light emitting diodes, at 2410. The method 2400 can further include disposing a second patterned screen above the substrate, at 2412. The method 2400 can further include screen-printing a second portion of the cross-linkable printing ink through the second patterned screen and onto one or both of at least a portion of the top surface of the substrate or at least a portion of a top surface of the first portion of the cross-linkable printing ink previously screen-printed onto at least a portion of the top surface of the substrate, at 2414. The method 2400 can further include disposing the retractable sheet comprising the flexible ultraviolet light emitting diodes between the second patterned screen and the substrate, at 2416. The method 2400 can further include emitting ultraviolet light from the ultraviolet light emitting diodes to cure the second portion of the cross-linkable printing ink to form a plurality of microstructures, wherein the top surface of the substrate and the plurality of microstructures define a plurality of microcavities therebetween, at 2418.

Some or all elements/steps of the method 2400 can be carried out by a device/apparatus, such as a 3D printing device. Some or all elements/steps of the method 2400 can be carried out programmatically, such as by using a computing device (e.g., 1700 and/or 1800), which can be separate from or a part of a device/apparatus for 3D printing.

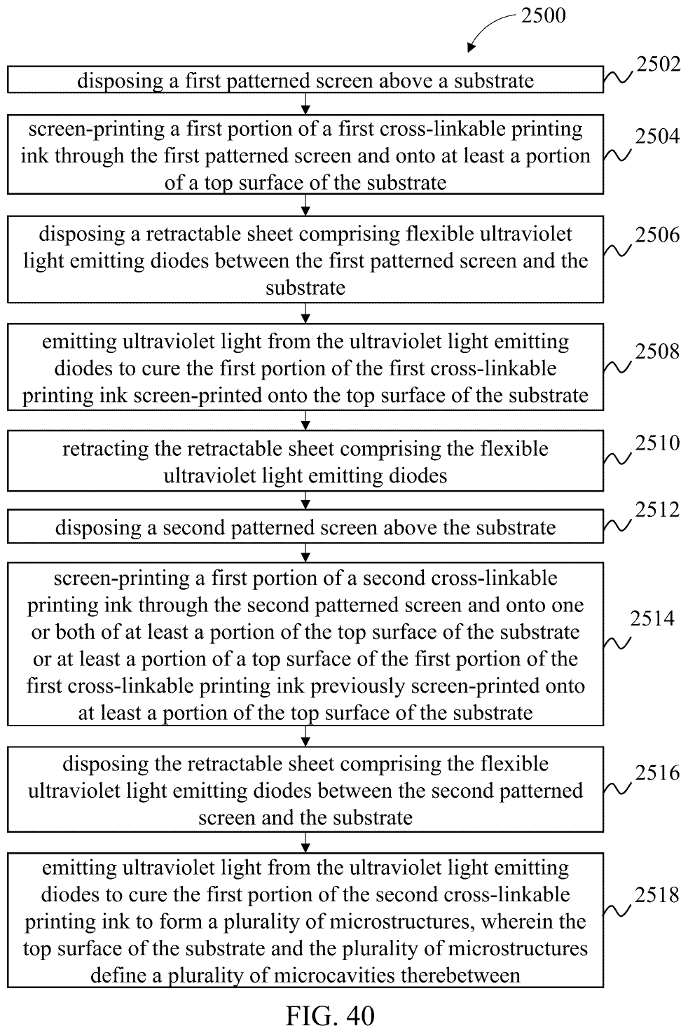

Referring now to FIG. 40, a method 2500 is illustrated that comprises disposing a first patterned screen above a substrate, at 2502. The method 2500 can further include screen-printing a first portion of a first cross-linkable printing ink through the first patterned screen and onto at least a portion of a top surface of the substrate, at 2504. The method 2500 can further include disposing a retractable sheet comprising flexible ultraviolet light emitting diodes between the first patterned screen and the substrate, at 2506. The method 2500 can further include emitting ultraviolet light from the ultraviolet light emitting diodes to cure the first portion of the first cross-linkable printing ink screen-printed onto the top surface of the substrate, at 2508. The method 2500 can further include retracting the retractable sheet comprising the flexible ultraviolet light emitting diodes, at 2510. The method 2500 can further include disposing a second patterned screen above the substrate, at 2512. The method 2500 can further include screen-printing a first portion of a second cross-linkable printing ink through the second patterned screen and onto one or both of at least a portion of the top surface of the substrate or at least a portion of a top surface of the first portion of the first cross-linkable printing ink previously screen-printed onto at least a portion of the top surface of the substrate, at 2514. The method 2500 can further include disposing the retractable sheet comprising the flexible ultraviolet light emitting diodes between the second patterned screen and the substrate, at 2516. The method 2500 can further include emitting ultraviolet light from the ultraviolet light emitting diodes to cure the first portion of the second cross-linkable printing ink to form a plurality of microstructures, wherein the top surface of the substrate and the plurality of microstructures define a plurality of microcavities therebetween, at 2518.

Some or all elements/steps of the method 2500 can be carried out by a device/apparatus, such as a 3D printing device. Some or all elements/steps of the method 2500 can be carried out programmatically, such as by using a computing device (e.g., 1700 and/or 1800), which can be separate from or a part of a device/apparatus for 3D printing.

### Examples

For some examples, the ink used was DI-7548 (Nagase ChemTex), an isobornyl acrylate-based resin ink which is UV curable using, e.g., a mercury vapor lamp. Stainless steel mesh screens were used (Microscreen, LLC). Various curing methods were used for different embodiments, e.g., using UV LEDs, to make the process more compatible with available equipment. In some embodiments, a DI-7548 ink was used as an encapsulant for printed Ag traces to prevent oxidation, and to create trace crossover areas in printed electronic circuits. Other printing inks were contemplated, such as other UV-curable or thermal-curing inks, such as those made from materials such as acrylate resin, epoxy, silicone, and/or the like. The ink material can be chosen based on the particular needs of different 3D screen-printing approaches and devices. In some embodiments, structures were printed using a DEK Horizon 03i automatic screen printer modified to facilitate in situ curing of dielectric ink layers.

### Cavity Fabrication

In some embodiments, flexible cavities were fabricated using a 3D screen printing method consisting of successive printing of dielectric layers. According to one example, a 7 mil (0.007 inches) thick polyethelene terepthalate (PET) substrates were prepared by cleaning the surface with 99% isopropyl alcohol (Fisher Chemical) to remove environmental contaminants. According to an example, a graphic layer can be screen-printed onto the surface of the PET substrate to create fiducials thereon. The fiducials may be used as markers or guides during the layer alignment process. According to some embodiments, additional markings may be needed for specific device fabrication or otherwise. According to examples, the final substrate preparation, including the cutting of vias and screen printing of conductive traces was then completed. In some examples, the first dielectric ink layer was deposited using a stainless steel mesh screen patterned with the cavity geometry, which is then cured using UV LEDs. This deposition/screen-printing and curing step can be repeated as necessary until the desired cavity dimensions (e.g., height, width, form factor, overhang, etc.) is reached. In some examples, a thermal film was then adhered to the top of the patterned cavities using a laminating roller press. In certain examples, additional device elements were then screen printed on top of the film to complete the devices.

### In Situ Curing

To reduce the potential for registration errors between layers of the printed channel, an in-situ UV curing system was developed which can be mounted onto the commercial screen printer. The 3D screen-printing setup consisted of a retractable, flexible UV blocking vinyl sheet with adhered UV LEDs that are extended between the substrate and the screen after printing a layer of dielectric ink. The sheet is supported by a designed system of detachable standoffs and rollers and is retracted away from the printing area when not in use. This setup uses LEDs of multiple wavelengths (e.g., 365 nm, 395 nm) to more closely simulate the broad-spectrum mercury vapor lamp LED systems. The retractable nature of the setup allows for the substrate to remain in the same place during curing, reducing the potential for registration errors, or other defects to occur during the curing process.

### Capping

A thermal laminating film made of PET (GBC, Acco Brands LLC) was chosen for capping the printed cavities. The thermal film was aligned on top of the completed trenches and passed through a laminating machine at 105° C. The combined heat and pressure activate the adhesive to ensure complete bonding between the laminating film and the printed devices. Due to the aspect ratio of the printed structures, the film adheres only to the printed dielectric ink which forms the cavity walls, leaving an open cavity of the designed geometry. This approach is a low cost, easy to manufacture method of cavity capping which can be incorporated into small batch fabrication or roll-to-roll printing processes. The laminating film is also compatible with the same printed inks as the substrate, allowing for screen printing of additional layers after capping. This allows for flexibility in the design of geometric cavities which may incorporate internal membrane structures and conductive interconnects.

Characterization of a printed microcavity was performed to analyze the structure's geometry and the impact of print parameters on the final structure. Evaluation was performed of an example print of a microfluidic cavity structure. Evaluation of the measured cavity size in relation to the designed geometry and height as a function of deposited layers was performed using stylus profilometry (Dektak 150, Tencor Alpha-step AS500). When evaluating the linear growth of the height of the printed structure relative to the thickness of each printed layer, it was determined that the thickness of the deposited layer is not affected by the height of the structure. The thickness per layer in the example was determined to be about 13.5 μm.

Computed tomography images (Zeiss Versa 620) were taken to analyze the 3D structure and calculate cross-sectional areas. As discussed above, a decrease in channel width from about 920 μm to about 726 μm was observed when printing parallel vs. perpendicular to the print direction. It was also observed that the sidewalls were formed at an angle of about 53°, likely due to the ink bleed of each successive layer flowing towards the substrate before curing.

As noted above regarding the analysis of channel narrowing during printing, three samples of each width were printed with 14 layers to achieve an approximate height of about 190 μm. The difference in the measured width of the channel compared to the designed width is likely due to ink bleed during the printing process and can vary based on the specific printing parameters and ink chosen. The measured samples were printed using the same print parameters, and measurements were all taken from samples printed parallel to squeegee direction.

When testing the example microfluidic capacitive test structure, approximate channel volume was calculated to be 2.7 μL using the designed channel area and measured height. The test setup uses a syringe pump for precise dispensing of water to a NanoPort connector adhered to the sample, and an impedance analyzer to measure capacitance (HP 4914A). Preliminary tests demonstrate measurable capacitance changes from about 3 pf to between about 7 pF and about 8 pF as fluid volume increases to the calculated channel volume, with an average linear approximation of about 1.39 pF/μL for the samples tested.

The example microcavity and microchannels and example 3D screen-printing processes described herein illustrate some of the approaches that can be used to successfully create microcavities on flexible substrates, e.g., for FHEs. These structures show promise for the fabrication of directly integrated flexible biosensors for wearable sensing systems, from membrane-based pressure sensors to small sample fluid collection and analysis, or optical microcavity based sensors. Characterization of the effects of geometry design and print orientation show that the effect of print bleed needs to be accounted for in the device design to ensure final devices meet the desired specifications.

The screen-printed approach offers significant flexibility for design and integration with broader printed flexible electronics, and reduces fabrication complexity, broadening the potential to develop low-cost flexible integrated sensing systems for wearable devices.

Other embodiments are contemplated. For example, other additive manufacturing approaches can be used to form a first part of a 3D printed microcavity or microchannel on a flexible substrate, while the remainder of the 3D printed microcavity or microchannel can be printed according to a 3D screen-printing approach, such as those described herein.

### Conclusions

Efforts have been made to ensure accuracy with respect to numbers used (e.g., amounts, temperature, etc.) but some experimental errors and deviations should be accounted for.

One skilled in the art will recognize many methods and materials similar or equivalent to those described herein, which could be used in the practicing the subject matter described herein. The present disclosure is in no way limited to just the methods and materials described.

Throughout this specification and the claims, the words “comprise,” “comprises,” and “comprising” are used in a non-exclusive sense, except where the context requires otherwise. It is understood that examples described herein include “consisting of” and/or “consisting essentially of”examples.

Where a range of values is provided, it is understood that each intervening value, to the tenth of the unit of the lower limit, unless the context clearly dictates otherwise, between the upper and lower limit of the range and any other stated or intervening value in that stated range, is encompassed. The upper and lower limits of these small ranges which may independently be included in the smaller rangers is also encompassed, subject to any specifically excluded limit in the stated range. Where the stated range includes one or both of the limits, ranges excluding either or both of those included limits are also included.

Many modifications and other examples set forth herein will come to mind to one skilled in the art to which this subject matter pertains having the benefit of the teachings presented in the foregoing descriptions and the associated drawings. Therefore, it is to be understood that the subject matter is not to be limited to the specific examples disclosed and that modifications and other examples are intended to be included within the scope of the appended claims. Although specific terms are employed herein, they are used in a generic and descriptive sense only and not for purposes of limitation.

It should be appreciated that all combinations of the foregoing concepts and additional concepts discussed in greater detail below (provided such concepts are not mutually inconsistent) are contemplated as being part of the inventive subject matter disclosed herein. In particular, the combinations of claimed subject matter appearing at the end of this disclosure are contemplated as being part of the inventive subject matter disclosed herein. It should be appreciated that terminology explicitly employed herein that also may appear in any disclosure incorporated by reference should be accorded a meaning consistent with the particular concepts disclosed herein.

In some embodiments, one or more of the operations, steps, elements, or processes described herein may be modified or further amplified as described below. Moreover, in some embodiments, additional optional operations may also be included. It should be appreciated that each of the modifications, optional additions, and/or amplifications described herein may be included with the operations previously described herein, either alone or in combination, with any others from among the features described herein.

The provided method description, illustrations, and process flow diagrams are provided merely as illustrative examples and are not intended to require or imply that the steps of the various embodiments must each or all be performed and/or should be performed in the order presented or described. As will be appreciated by one of skill in the art, the order of steps in some or all of the embodiments described may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an,” or “the” is not to be construed as limiting the element to the singular. Further, any reference to dispensing, disposing, depositing, dispersing, conveying, injecting, inserting, communicating, and other such terms of art are not to be construed as limiting the element to any particular means or method or apparatus or system, and is taken to mean conveying the material within the receiving vessel, solution, conduit, or the like by way of any suitable method.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation. Specific equipment and materials described in the examples are for illustration only and not for purposes of limitation. For instance, any and all articles, portions of articles, structures, bulk materials, and/or the like, having any form factor, scale, dimensions, aesthetic attributes, material properties, internal structures, and/or mechanical properties, which are formed according to any of the disclosed methods, approaches, processes, or variations thereof, using any devices, equipment, apparatuses, systems, or variations thereof, using any of the build materials/resins described herein or variations thereof, are all contemplated and covered by the present disclosure. None of the examples provided are intended to, nor should they, limit in any way the scope of the present disclosure.

The various portions of the present disclosure, such as the Background, Summary, Brief Description of the Drawings, and Abstract sections, are provided to comply with requirements of the MPEP and are not to be considered an admission of prior art or a suggestion that any portion or part of the disclosure constitutes common general knowledge in any country in the world. The present disclosure is provided as a discussion of the inventor's own work and improvements based on the inventor's own work. See, e.g., Riverwood Int'l Corp. v. R. A. Jones & Co., 324 F.3d 1346, 1354 (Fed. Cir. 2003).

In some embodiments, one or more of the operations, steps, or processes described herein may be modified or further amplified as described below. Moreover, in some embodiments, additional optional operations may also be included. It should be appreciated that each of the modifications, optional additions, and/or amplifications described herein may be included with the operations previously described herein, either alone or in combination, with any others from among the features described herein.

Although specific advantages have been enumerated above, various embodiments may include some, none, or all of the enumerated advantages.

Other technical advantages may become readily apparent to one of ordinary skill in the art after review of the following figures and description.

It should be understood that, although exemplary embodiments are illustrated in the figures and described below, the principles of the present disclosure may be implemented using any number of techniques, whether currently known or not. The present disclosure should in no way be limited to the examples, experimental results, exemplary embodiments, preferred configurations, illustrated equipment, disclosed processes, or particular implementations and techniques illustrated in the drawings and described below.

The provided method description, illustrations, and process flow diagrams are provided merely as illustrative examples and are not intended to require or imply that the steps of the various embodiments must each or all be performed and/or should be performed in the order presented or described. As will be appreciated by one of skill in the art, the order of steps in some or all of the embodiments described may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an,” or “the” is not to be construed as limiting the element to the singular. Further, any reference to dispensing, disposing, depositing, dispersing, conveying, injecting, conveying, inserting, communicating, and other such terms of art are not to be construed as limiting the element to any particular means or method or apparatus or system, and is taken to mean conveying the material within the receiving vessel, solution, conduit, or the like by way of any suitable method.

Unless otherwise indicated, all numbers expressing quantities of equipment, number of steps, material quantities, material masses, material volumes, operating conditions, and so forth used in the specification and claims are to be understood as being modified in all instances by the term “about.” Accordingly, unless indicated to the contrary, the numerical parameters set forth in the present specification and attached claims are approximations that can vary depending upon the desired properties sought to be obtained by the present application. Generally, the term “about,” as used herein when referring to a measurable value such as an amount of weight, time, volume, ratio, temperature, etc., is meant to encompass ±50% of the stated value. For example, a value of “1,000,” which would be construed from above as meaning “about 1,000,” indicates a range of values from 500 to 1,500, inclusive of all values and ranges therebetween. As another example, a value of “about 1,000” should be taken to indicate any single value or sub-range of values from 500 to 1,500, inclusive of the values 500 and/or 1,500. As such, if a value of “about 1,000” is disclosed or claimed, this disclosure or claim element includes, for example, the value of 500, the value of 500.0000000000001, the value of 500.1, the value of 501, . . . the value of 1,000, . . . the value of 1,499.9999999, the value of 1,500, and all other values, ranges, or sub-ranges, therebetween, including values interstitial to adjacent integers or whole numbers, to any decimal place.

Generally, the term “substantially,” as used herein when referring to a measurable value, is meant to encompass ±50% of the stated value. Generally, the term “substantially,” as used herein with regard to a discrete position or orientation of a piece of equipment, component, or subcomponent, is meant to encompass the discrete position ±50% of the discrete position. Generally, the term “substantially,” as used herein with regard to a location of a piece of equipment, component, or subcomponent along a total range of travel of that equipment, component, or subcomponent, is meant to encompass ±50% of the location of the equipment, component, or subcomponent with regard to the total range of travel of that piece of equipment, component, or subcomponent, including translational travel, rotational travel, and extending travel in any direction, orientation, or configuration. As such, the use of the phrase “substantially disposed within a container” would be construed from above as meaning that greater than or equal to 50% of the subject element is disposed within the container. Likewise, the use of the phrase “substantially positioned within a bath” would be construed from above as meaning that greater than or equal to 50% of the subject element is positioned within the bath.

All transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

Conventional terms in the fields of additive manufacturing, materials science, and chemistry have been used herein. The terms are known in the art and are provided only as a non-limiting example for convenience purposes. Accordingly, the interpretation of the corresponding terms in the claims, unless stated otherwise, is not limited to any particular definition. Thus, the terms used in the claims should be given their broadest reasonable interpretation.

Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation. Specific equipment and materials described in the examples are for illustration only and not for purposes of limitation. For instance, any and all articles, portions of articles, structures, bulk materials, and/or the like, having any form factor, scale, dimensions, aesthetic attributes, material properties, internal structures, and/or mechanical properties, which are formed according to any of the disclosed methods, approaches, processes, or variations thereof, using any devices, equipment, apparatuses, systems, or variations thereof, using any of the build material, printing mixture, ink, yield-stress support material, or other material compositions described herein or variations thereof, are all contemplated and covered by the present disclosure. None of the examples provided are intended to, nor should they, limit in any way the scope of the present disclosure.

In this Detailed Description, various features may have been grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments may be combined with each other in various combinations or permutations. The scope of the embodiments should be determined with reference to the appended claims, along with the full scope of equivalents to which such claims are entitled.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that some or all of the parameters, dimensions, materials, equipment, processes, methods, and configurations described herein are meant to be preferred examples and that the actual parameters, dimensions, materials, and/or configurations will depend upon the specific application or applications for which the inventive teachings are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein “at. %” refers to atomic percent, “vol. %” refers to volume percent, and “wt. %” refers to weight percent. However, in certain embodiments when “at. %” is utilized, the values described may also describe “vol. %” and/or “wt. %,” when “vol. %” is utilized, the values described may also describe “at. %” and/or “wt. %,” and when “wt. %” is utilized, the values described may also describe “at. %” and/or “vol. %.” For example, if “20 at. %” is described in one embodiment, in other embodiments the same description may refer to “20 wt. %” or “20 vol. %.” As a result, all “at. %” values should be understood to also refer to “wt. %” in some instances and “vol. %” in other instances, all “vol. %” values should be understood to also refer to “wt. %” values in some instances and “at. %” in other instances, and all “wt. %” values should be understood to refer to “at. %”in some instances and “vol. %”in other instances.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

1. A method comprising:
providing a substrate comprising a planar substrate material and a first electrode material coupled to at least a portion of a top surface of the planar substrate material;
disposing one or more volumes of an ink through one or more patterned screens onto a top surface of the substrate;
at least partially curing the one or more volumes of the ink to form a plurality of microstructures on the top surface of the substrate, wherein the top surface of the substrate and the plurality of microstructures define one or more microcavities; and
disposing a capping film over at least a portion of the plurality of microstructures to encapsulate at least a portion of the one or more microcavities between the top surface of the substrate and a bottom surface of the capping film.

2. The method of claim 1, wherein the at least partially curing the one or more volumes of the ink is performed using a curing device selected from among: a heat source, a light source, a light emitting diode, a lamp, a bulb, an ultraviolet emission source, a heater, or a mercury vapor lamp.

3. The method of claim 2, wherein the curing device is disposed within or on a retractable sheet mounted on standoff rollers configured to move along board rails positioned between or about the substrate and the one or more patterned screens.

4. The method of claim 1, wherein said disposing the capping film over at least a portion of the plurality of microstructures forms one or more inlets into the one or more microcavities and one or more outlets from the one or more microcavities.

5. The method of claim 1, wherein the substrate comprises a planar substrate material and a first electrode material coupled to at least a portion of the top surface of the planar substrate material.

6. The method of claim 5, further comprising:
disposing a second electrode material onto at least a portion of a top surface of the capping film.

7. The method of claim 1, wherein the one or more volumes of the ink, once screen-printed and supported on the top surface of the substrate, forms one or more dielectric layers supported on the top surface of the substrate.

8. The method of claim 1, wherein the ink comprises one or more of: a resin, an isobornyl acrylate-based resin, PDMS, a ceramic, an acrylic, polystyrene, polycarbonate, polyvinyl chloride, a conductive ink, a solvent, a binder, an additive, a pigment, a carrier, or a rheologically modifier.

9. The method of claim 1, further comprising:
disposing a first electrode material onto the substrate to form the top surface of the substrate.

10. The method of claim 9, further comprising:
disposing a laminate film over top surfaces of the plurality of microstructures to encapsulate the plurality of microcavities between a bottom surface of the laminate film and the top surface of the substrate.

11. The method of claim 10, further comprising:
disposing a second electrode material onto a top surface of the laminate film.

12. The method of claim 10, further comprising:
disposing, onto the top surface of the laminate film or a top surface of the one more volumes of ink disposed on the substrate, one or more of: an electrode layer, a resin layer, or a laminate layer to create additional microcavities in a vertically stacked configuration, with or without interconnection between the plurality of microcavities and the additional microcavities.

13. The method of claim 1, further comprising:
disposing a graphic layer onto the top surface of the substrate before screen-printing the one or more volumes of the ink onto the top surface of the substrate in order to dispose one or more fiducials on the top surface of the substrate.

14. The method of claim 1, further comprising:
removing at least a portion of an insulating layer of the substrate to expose at the top surface of the substrate one or more electrical traces or one or more fiducials.

15. A method comprising:
disposing a first patterned screen above a substrate;
screen-printing a first portion of a resin ink through the first patterned screen and onto at least a portion of a top surface of the substrate;
after screen-printing the first portion of the resin ink through the first patterned screen, disposing a retractable ultraviolet light emitting diodes between the first patterned screen and the substrate;
emitting ultraviolet light from the ultraviolet light emitting diodes to at least partially cure the first portion of the resin ink screen-printed onto the top surface of the substrate;
retracting the retractable ultraviolet light emitting diodes;
disposing a second patterned screen above the substrate;
screen-printing a second portion of the resin ink through the second patterned screen and onto one or both of at least a portion of the top surface of the substrate or at least a portion of a top surface of the first portion of the resin ink previously screen-printed onto at least a portion of the top surface of the substrate;
after screen-printing the second portion of the resin ink through the second patterned screen, disposing the retractable ultraviolet light emitting diodes between the second patterned screen and the substrate; and
emitting ultraviolet light from the ultraviolet light emitting diodes to at least partially cure the second portion of the resin ink to form a plurality of microstructures, wherein the top surface of the substrate and the plurality of microstructures define a plurality of microcavities therebetween.

16. The method of claim 15, wherein the ultraviolet light emitting diodes are comprised within a mercury vapor lamp.

17. The method of claim 15, wherein the first and second portions of the resin ink, once screen-printed and supported on the top surface of the substrate, form one or more dielectric layers supported on the top surface of the substrate.

18. The method of claim 15, wherein the screen-printing of the second portion of the resin ink onto one or more of the top surface of the substrate or the top surface of the first portion of the resin ink screen-printed onto the top surface of the substrate forms one or more microcavities above the top surface of the substrate.

19. The method of claim 15, further comprising:
disposing a first electrode material onto the substrate to form the top surface of the substrate;
after screen-printing the second portion of the resin ink through the second patterned screen and at least partially curing the second portion of the resin ink, disposing a laminate film over top surfaces of the plurality of microstructures to encapsulate the plurality of microcavities between a bottom surface of the laminate film and the top surface of the substrate; and
disposing a second electrode material onto a top surface of the laminate film.

20. An apparatus comprising:
at least one processor; and
at least one memory comprising instructions stored therein that, when executed by the at least one processor, cause the apparatus to perform at least:
positioning one or more patterned screens above or onto a top surface of a substrate, the substrate comprising a first electrode material coupled to at least a portion of the top surface of the planar substrate material;
disposing one or more volumes of an ink through at least a portion of the one or more patterned screens onto the top surface of the substrate;
at least partially curing the one or more volumes of the ink to form a plurality of microstructures on the top surface of the substrate, wherein the top surface of the substrate and the plurality of microstructures define one or more microcavities; and
disposing a capping film over at least a portion of the plurality of microstructures to encapsulate at least a portion of the one or more microcavities between the top surface of the substrate and a bottom surface of the capping film.
